(19) United States
(12) Patent Application Publication
(10) Pub. No.: US 2024/0363449 A1
(43) Pub. Date: Oct. 31, 2024

(54) INFORMATION PROCESSING DEVICE, INFERENCE DEVICE, AND MACHINE LEARNING DEVICE

(71) Applicant: EBARA CORPORATION, Tokyo (JP)

(72) Inventors: CHING WEI HUANG, Tokyo (JP); HIROFUMI OTAKI, Tokyo (JP); TAKAMASA NAKAMURA, Tokyo (JP); SHO ICHINOSE, Tokyo (JP)

(73) Assignee: EBARA CORPORATION, Tokyo (JP)

(21) Appl. No.: 18/632,334

(22) Filed: Apr. 11, 2024

(30) Foreign Application Priority Data
Apr. 28, 2023 (JP) 2023-075056

(51) Int. Cl. H01L 21/66; H01L 21/67

(52) U.S. Cl. CPC H01L 22/12; H01L 21/67219; H01L 21/67253

(57) ABSTRACT

An information processing device includes: a reference information acquisition part that acquires, as reference information, a reference processing quantity and reference device information in a reference device corresponding to a substrate processing apparatus serving as a reference; a comparison information acquisition part that acquires, as comparison information, a comparison processing quantity and comparison device information in a comparison device corresponding to the substrate processing apparatus serving as a comparison target of the reference device; and a diagnostic processing part that generates diagnostic information including at least one of a cause of a time when a difference occurs between the reference processing quantity and the comparison processing quantity and a countermeasure for eliminating the difference, based on the reference information and the comparison information.

### CROSS-REFERENCE TO RELATED APPLICATION

This application claims the priority benefit of Japan application serial no. 2023-075056, filed on Apr. 28, 2023. The entirety of the above-mentioned patent application is hereby incorporated by reference herein and made a part of this specification.

### BACKGROUND

### Technical Field

The disclosure relates to an information processing device, an inference device, a machine learning device, an information processing method, an inference method, and a machine learning method.

### Related Art

One of substrate processing apparatuses that perform various substrate processings on substrates such as semiconductor wafers is a substrate processing apparatus that performs chemical-mechanical polishing (CMP). Such a substrate processing apparatus includes, for example, a polishing unit that performs a polishing processing on the substrate, a finishing unit that performs a finishing processing (e.g., a washing processing and a drying processing) on the substrate after the polishing processing, and a transport unit that performs a transport processing of transporting the substrate between each unit. The substrate processing apparatus is configured to perform a series of processings by causing each unit to act sequentially (e.g., see Patent Document 1: Japanese Patent Application Laid-Open No. 2007-301690).

As an indicator for managing the operation of the substrate processing apparatus, a processing quantity of substrates per unit time (unit time processing quantity) is used. In the substrate processing apparatus, various mechanical mechanism groups included in each unit act in cooperation while referring to various parameter groups such as device setting information and recipe information. Thus, in the case where an actual measured value of the unit time processing quantity deviates from a target value of the unit time processing quantity, as an operation of diagnosing the state of the substrate processing apparatus, it is necessary to specify a cause, i.e., which setting value in the various parameter groups is affecting, or which adjustment state in the various mechanical mechanism groups is affecting, and implement a countermeasure against it. However, since various parameter groups and mechanism groups are complexly related, it is a difficult operation requiring advanced knowledge and extensive experience to quickly and accurately specify a cause and implement a countermeasure.

### SUMMARY

An information processing device according to an aspect of the disclosure is an information processing device diagnosing a state of a substrate processing apparatus. The substrate processing apparatus includes: a substrate processing unit that performs a substrate processing on a substrate; and a transport processing unit that performs a transport processing of transporting the substrate before the substrate processing and after the substrate processing. The information processing device includes a reference information acquisition part, a comparison information acquisition part, and a diagnostic processing part. The reference information acquisition part acquires a reference processing quantity and reference device information as reference information. The reference processing quantity indicates a processing quantity of the substrate per unit time of a time when a reference processing action repeating the substrate processing and the transport processing is performed in a reference device corresponding to the substrate processing apparatus serving as a reference, and the reference device information is related to the reference device of the time when the reference processing action is performed. The comparison information acquisition part acquires a comparison processing quantity and comparison device information as comparison information. The comparison processing quantity indicates a processing quantity of the substrate per unit time of a time when a comparison processing action repeating the substrate processing and the transport processing is performed in a comparison device corresponding to the substrate processing apparatus serving as a comparison target of the reference device, and the comparison device information is related to the comparison device of the time when the comparison processing action is performed. The diagnostic processing part generates diagnostic information comprising at least one of a cause of a time when a difference occurs between the reference processing quantity and the comparison processing quantity and a countermeasure for eliminating the difference, based on the reference information acquired by the reference information acquisition part and the comparison information acquired by the comparison information acquisition part.

According to the information processing device according to an aspect of the disclosure, the diagnostic processing part generates the diagnostic information including at least one of a cause of a time when a difference occurs between the reference processing quantity and the comparison processing quantity and a countermeasure for eliminating the difference, based on the reference information including the reference processing quantity and the reference device information in the reference device corresponding to the substrate processing apparatus serving as the reference, and the comparison information including the comparison processing quantity and the comparison device information in the comparison device corresponding to the substrate processing apparatus serving as the comparison target of the reference device. Thus, it is possible to diagnose the state of the substrate processing apparatus quickly and accurately when a difference occurs between the reference processing quantity and the comparison processing quantity.

Problems, configurations, and effects other than those described above will be illustrated in the embodiments for carrying out the disclosure to be described later.

### BRIEF DESCRIPTION OF DRAWINGS

FIG. 1 is an overall configuration view showing an example of a substrate processing system 1.

FIG. 2 is a schematic plan view showing an example of a substrate processing apparatus 2.

FIG. 3 is a schematic view showing an example of a transport route (first half) of a wafer W in the substrate processing apparatus 2.

FIG. 4 is a schematic view showing an example of a transport route (second half) of the wafer W in the substrate processing apparatus 2.

FIG. 5 is a perspective view showing an example of first to fourth polishing units 22A to 22D.

FIG. 6 is a perspective view showing an example of first finishing units 230A and 230B which perform a roll sponge washing processing.

FIG. 7 is a perspective view showing an example of second finishing units 231A and 231B which perform a pen sponge washing processing.

FIG. 8 is a perspective view showing an example of third finishing units 232A and 232B which perform a drying processing.

FIG. 9 is a schematic side view showing an example of a substrate transport part 24 (second transport units 241A and 241B and transfer robot 243).

FIG. 10 is a schematic side view showing an example of the substrate transport part 24 (third transport units 242A and 242B and transfer robot 243).

FIG. 11 is a block diagram showing an example of the substrate processing apparatus 2.

FIG. 12 is a hardware configuration view showing an example of a computer 900.

FIG. 13 is a data structure view showing an example of production history information managed by a database device 3.

FIG. 14 is a data structure view showing an example of test information 31 managed by the database device 3.

FIG. 15 is a data structure view showing an example of simulation information 32 managed by the database device 3.

FIG. 16 is a block diagram showing an example of a machine learning device 4.

FIG. 17 is a view showing an example of a learning model 18 and learning data 17.

FIG. 18 is a flowchart showing an example of a machine learning method performed by the machine learning device 4.

FIG. 19 is a block diagram showing an example of an information processing device 5A according to the first embodiment.

FIG. 20 is a function illustrative view showing an example of the information processing device 5A according to the first embodiment.

FIG. 21 is a flowchart showing an example of an information processing method performed by the information processing device 5A according to the first embodiment.

FIG. 22 is a block diagram showing an example of an information processing device 5B according to a second embodiment.

FIG. 23 is a flowchart showing an example of an information processing method performed by the information processing device 5B according to the second embodiment.

### DESCRIPTION OF EMBODIMENTS

Embodiments of the disclosure provide an information processing device, an inference device, a machine learning device, an information processing method, an inference method, and a machine learning method capable of quickly and accurately diagnosing a state of a substrate processing apparatus.

Hereinafter, embodiments for carrying out the disclosure will be described with reference to the drawings. In the following, a range necessary for descriptions for achieving the objective of the disclosure will be schematically illustrated, a range necessary for descriptions of the relevant portion of the disclosure will be mainly described, and parts for which descriptions are omitted will be regarded as based on the conventional art.

### First Embodiment

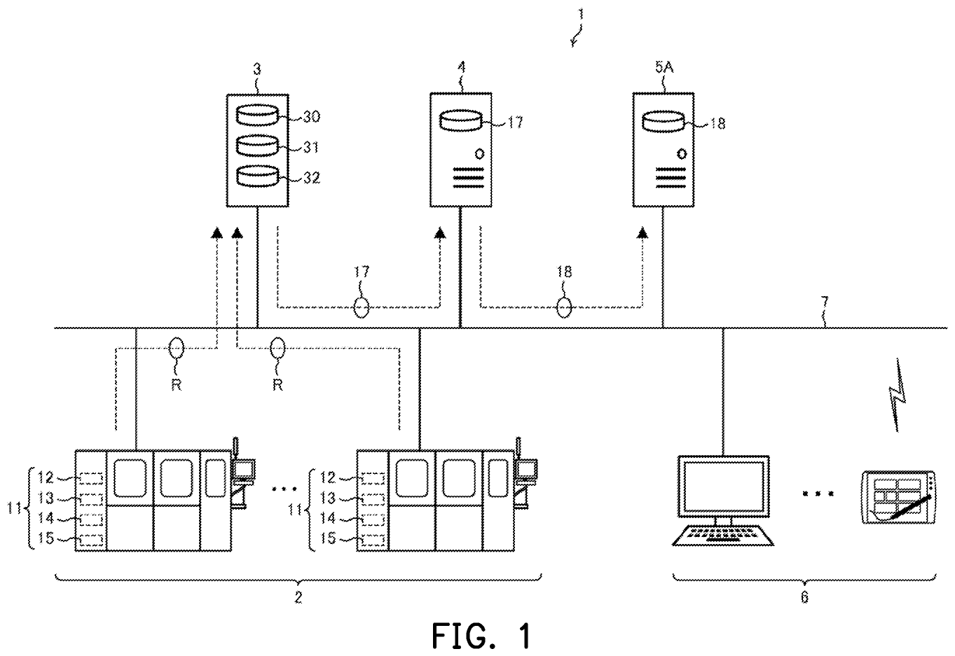

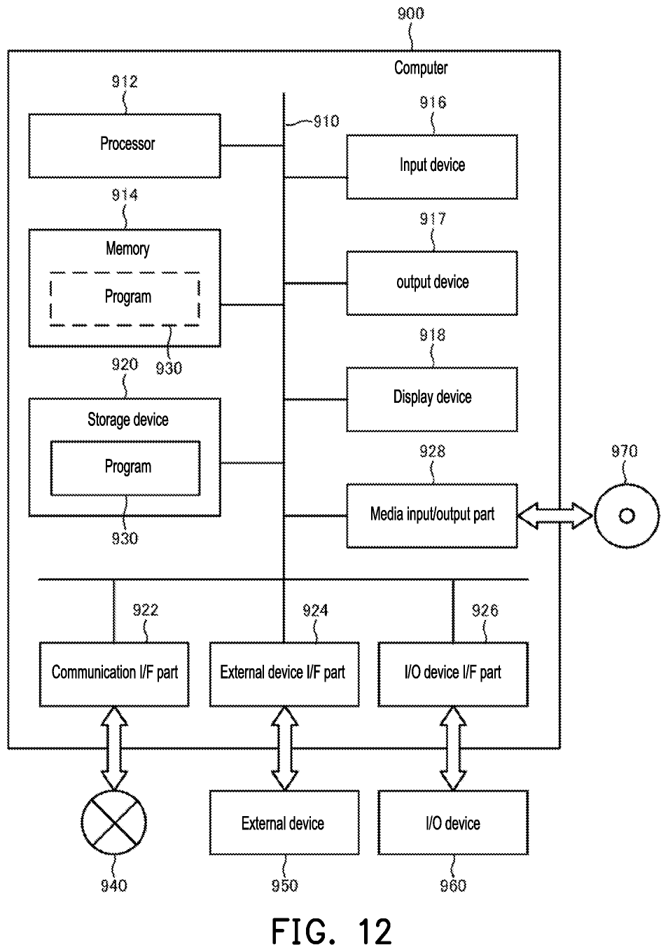

FIG. 1 is an overall configuration view showing an example of a substrate processing system 1. The substrate processing system 1 according to this embodiment includes, as main components, a substrate processing apparatus 2, a database device 3, a machine learning device 4, an information processing device 5A, and a user terminal device 6. Each of the devices 2 to 6 includes, for example, a general-purpose or dedicated computer (see FIG. 12 to be described later), and is configured to be connected to a wired or wireless network 7 to be capable of sending and receiving various data (in FIG. 1, transmission and reception of a part of the data are indicated by broken line arrows) to each other. The quantities of each device 2 to 6 and the connection configuration of the network 7 are not limited to the example in FIG. 1 and may be changed as appropriate.

The substrate processing apparatus 2 includes a substrate processing unit (to be described in detail later) that performs various substrate processings on a substrate (hereinafter referred to as a “wafer”) W such as a semiconductor wafer, and a transport processing unit (to be described in detail later) that transports the wafer W. In this embodiment, the substrate processing apparatus 2 includes a polishing unit and a finishing unit as the substrate processing unit, and performs a chemical-mechanical polishing processing (hereinafter referred to as a “polishing processing”), a finishing processing, a transport processing, etc. on the wafer W by causing the polishing unit, the finishing unit, and the transport processing unit to act. At that time, the substrate processing apparatus 2 controls actions of the polishing unit, the finishing unit, and the transport processing unit while referring to device setting information 12 that defines action contents of the polishing unit, the finishing unit, and the transport processing unit, and recipe information 13 that defines processing contents of the polishing processing and the finishing processing. Then, the substrate processing apparatus 2 performs a processing action (automatic operation) repeating the polishing processing, the finishing processing, the transport processing, etc. on a plurality of wafers W.

The substrate processing apparatus 2 sends various reports R to the database device 3 and the like in response to performance of the processing action. The various reports R include, for example, process information that specifies the wafer W and the time of each processing of the time when the processing action is performed, device information 11 that includes the state and the setting value of each part of the substrate processing apparatus 2 of the time when the processing action is performed, operation information of an operator with respect to the substrate processing apparatus 2, etc. The device information 11 includes, for example, device setting information 12, recipe information 13, consumable information 14, event information 15, etc. Details of each information will be described later.

The database device 3 is a device that manages: production history information 30 related to the history of the time when the processing action (automatic operation) is performed using the substrate processing apparatus 2 for regular production; test information 31 related to a test result of the time when a test action (test operation) the same as the processing action is performed using a test device (not shown); and simulation information 32 related to a simulation result of the time when a simulation action (simulation operation) the same as the processing action is performed using a simulation device (not shown). The test device may be replaced with the substrate processing apparatus 2 for regular production or may be a dedicated device capable of testing the processing action. Further, the simulation device may be replaced with the database device 3 or may be a dedicated device capable of simulating the processing action.

The production history information 30 registers various reports R sent from the substrate processing apparatus 2 for regular production when the processing action is performed in the substrate processing apparatus 2 for regular production. The test information 31 registers various reports R (test results) and test conditions sent from the test device when the test action is performed according to predetermined test conditions in the test device. The simulation information 32 registers simulation results and simulation conditions sent from the simulation device when the simulation action is performed according to predetermined simulation conditions in the simulation device. The simulation result includes, for example, the same information as the report R.

The machine learning device 4 is a device that acts as a main body of a learning phase of machine learning. For example, the machine learning device 4 refers to the production history information 30, the test information 31, and the simulation information 32 registered in the database device 3 and acquires a plurality of sets of learning data 17. Then, based on the plurality of sets of learning data 17, the machine learning device 4 generates, by machine learning, a learning model 18 to be used in the information processing device 5A. The learned learning model 18 is provided to the information processing device 5A via the network 7, recording media, etc.

The information processing device 5A is a device that acts as a main body of an inference phase of machine learning and diagnoses the state of the substrate processing apparatus 2 using the learning model 18 provided from the machine learning device 4. As a result of diagnosing the state of the substrate processing apparatus 2, the information processing device 5A generates diagnostic information. The substrate processing apparatus 2 serving as a diagnostic target may be a substrate processing apparatus 2 before being shipped from an assembly plant of the substrate processing apparatus 2, or may be a substrate processing apparatus 2 installed at a production line after being shipped from the assembly plant.

The user terminal device 6 is a terminal device used by an operator, and may be a stationary device or a portable device. For example, the user terminal device 6 receives various input operations via a display screen such as an application program and a web browser, and displays various information (e.g., notifications of events, the device information 11, the production history information 30, the test information 31, the simulation information 32, the diagnostic information, etc.) via the display screen.

### (Substrate Processing Apparatus)

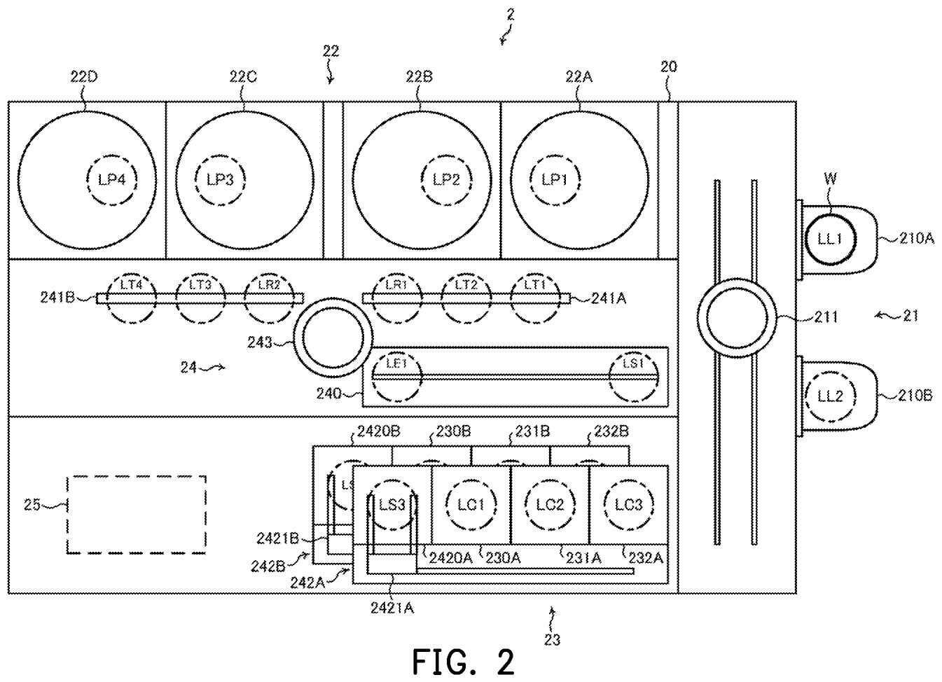

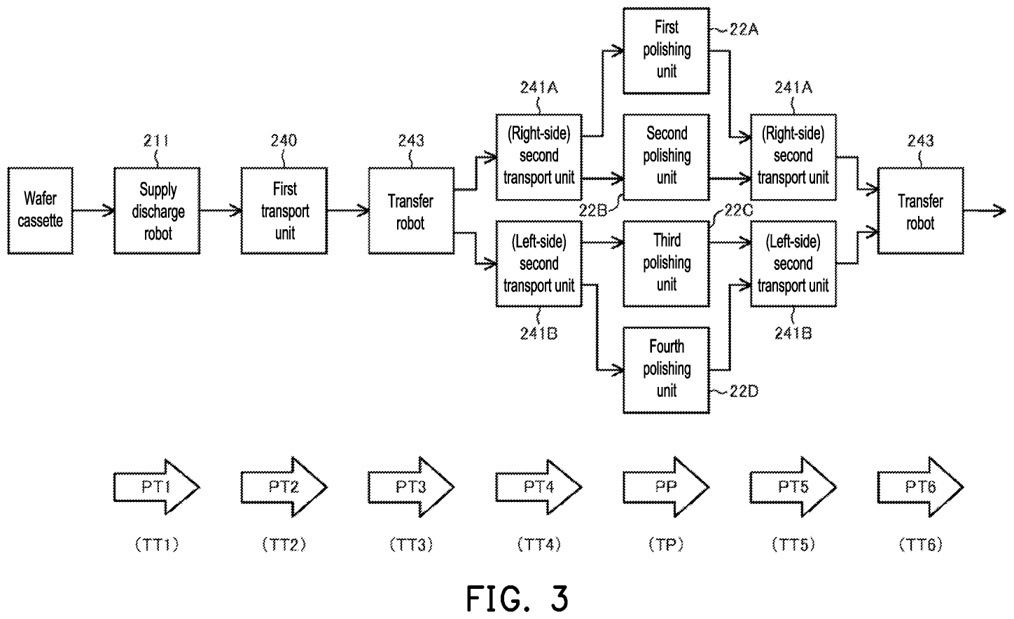

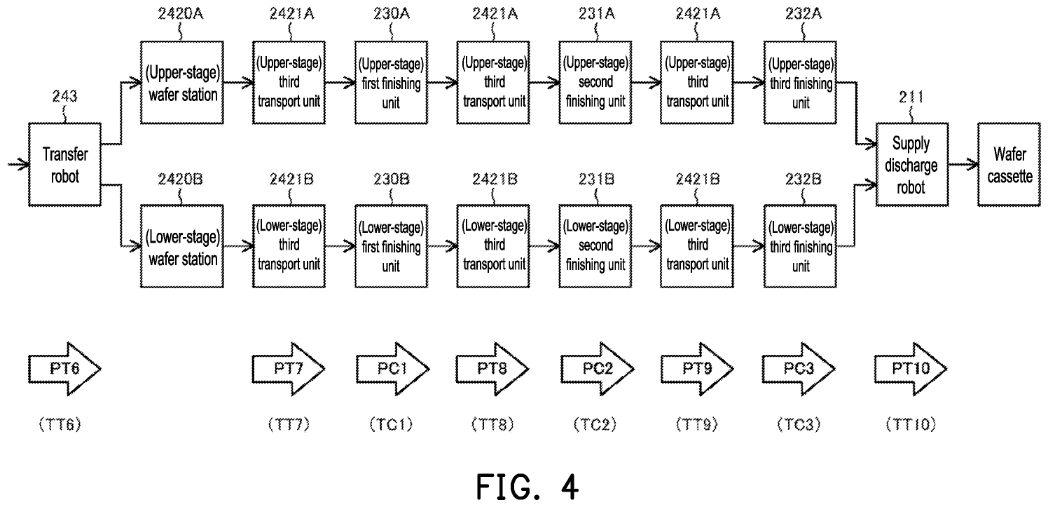

FIG. 2 is a schematic plan view showing an example of the substrate processing apparatus 2. FIG. 3 and FIG. 4 are schematic views showing an example of a transport route of the wafer W in the substrate processing apparatus 2. The substrate processing apparatus 2 is configured to include a load/unload part 21, a polishing part 22, a finishing part 23, a substrate transport part 24, and a control unit 25, inside a housing 20 in a substantially rectangular shape in a plan view.

### (Load/Unload Part)

The load/unload part 21 includes first and second front load parts 210A and 210B on which wafer cassettes (substrate cassettes such as FOUPs) capable of storing a large number of wafers W in the up-down direction are placed at wafer cassette positions LL1 and LL2, and a supply discharge robot 211 that performs supply and discharge of the wafer W.

The supply discharge robot 211 is configured to be movable in the horizontal direction along the short-side direction of the housing 20, and is configured to be movable in the up-down direction and the turning direction. The supply discharge robot 211 includes upper and lower hands (not shown) in two stages for handing over the wafer W. One of the hands is used when handing over a wafer W before the polishing processing, and the other of the hands is used when handing over a wafer W after the finishing processing. For example, the hands are configured to be extendable and capable of flipping the wafer W upside down.

A transport processing PT of the wafer W may include transport processings PT1 to PT10 respectively performed during transport processing times TT1 to TT10. As a transport processing PT of the wafer W, the supply discharge robot 211 performs a substrate supply processing PT1 of taking out a wafer W before the polishing processing from the wafer cassette and supplying the wafer W to a first transport unit 240, and a substrate discharge processing PT10 of receiving a wafer W after the finishing processing from the finishing part 23 (in this embodiment, third finishing units 232A and 232B) and storing the wafer W to the wafer cassette.

### (Polishing Part)

The polishing part 22 includes a plurality (four in this embodiment) of polishing units 22A to 22D that respectively perform a polishing processing PP on the wafer W during a polishing processing time TP. In this embodiment, the first to fourth polishing units 22A to 22D are arranged side by side along the long-side direction of the housing 20 and perform the polishing processing PP on the wafer W in parallel at polishing positions LP1 to LP4. The first to fourth polishing units 22A to 22D are configured to be accessible at polishing unit handover positions LT1 to LT4 for handing over the wafer W. The polishing unit handover positions LT1 to LT4 are individually set for the first to fourth polishing units 22A to 22D.

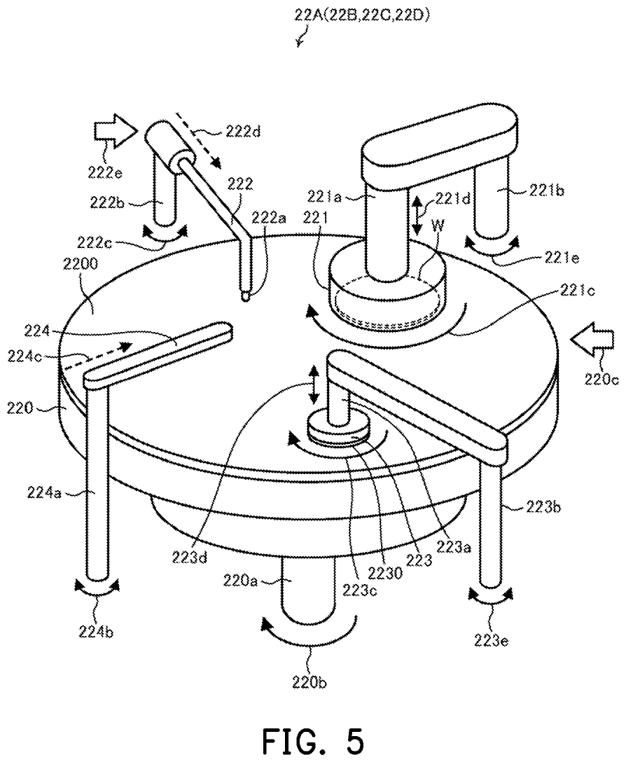

FIG. 5 is a perspective view showing an example of the first to fourth polishing units 22A to 22D. In this embodiment, the basic configuration and function of the first to fourth polishing units 22A to 22D will be described as common among each other.

Each of the first to fourth polishing units 22A to 22D includes a polishing table 220 that rotatably supports a polishing pad 2200 having a polishing surface, a top ring (substrate holding part) 221 that rotatably holds the wafer W and polishes the wafer W while pressing the wafer W against the polishing pad 2200 on the polishing table 220, a polishing fluid supply part 222 that supplies a polishing fluid to the polishing pad 2200, a dresser 223 that rotatably supports a dresser disk 2230 and causes the dresser disk 2230 to contact the polishing surface of the polishing pad 2200 to dress the polishing pad 2200, and an atomizer 224 that sprays a washing fluid to the polishing pad 2200.

The polishing table 220 includes a rotational movement mechanism part 220b that is supported by a polishing table shaft 220a and rotationally drives the polishing table 220 around its axis, and a temperature adjustment mechanism part 220c that adjusts the surface temperature of the polishing pad 2200.

The top ring 221 includes a rotational movement mechanism part 221c that is supported by a top ring shaft 221a movable in the up-down direction and rotationally drives the top ring 221 around its axis, an up-down movement mechanism part 221d that causes the top ring 221 to move in the up-down direction, and a swinging movement mechanism part 221e that causes the top ring 221 to turn (swing) around a support shaft 221b as a center of turning. The rotational movement mechanism part 221c, the up-down movement mechanism part 221d, and the swinging movement mechanism part 221e function as substrate movement mechanism parts that cause movement of the relative position between the polishing pad 2200 and the polished surface of the wafer W.

The polishing fluid supply part 222 includes a polishing fluid supply nozzle 222a that supplies a polishing fluid to the polishing surface of the polishing pad 2200, a swinging movement mechanism part 222c that is supported by a support shaft 222b and causes the polishing fluid supply nozzle 222a to turn and move around the support shaft 222b as a center of turning, a flow rate adjustment part 222d that adjusts the flow rate of the polishing fluid, and a temperature adjustment mechanism part 222e that adjusts the temperature of the polishing fluid. The polishing fluid may be a polishing liquid (slurry) or pure water, and may further contain a chemical solution, or a dispersant may be added to the polishing liquid.

The dresser 223 includes a rotational movement mechanism part 223c that is supported by a dresser shaft 223a movable in the up-down direction and rotationally drives the dresser 223 around its axis, an up-down movement mechanism part 223d that causes the dresser 223 to move in the up-down direction, and a swinging movement mechanism part 223e that causes the dresser 223 to turn and move around a support shaft 223b as a center of turning.

The atomizer 224 includes a swinging movement mechanism part 224b that is supported by a support shaft 224a and causes the atomizer 224 to turn and move around the support shaft 224a as a center of turning, and a flow rate adjustment part 224c that adjusts the flow rate of the washing fluid. The washing fluid is a mixed fluid of a liquid (e.g., pure water) and a gas (e.g., nitrogen gas) or is a liquid (e.g., pure water).

In the polishing processing PP, by moving the top ring 221 to the polishing unit handover positions LT1 to LT4 and adsorbing and holding the wafer W before the polishing processing onto the lower surface of the top ring 221, the wafer W before the polishing processing is received from second transport units 241A and 241B. Then, by moving the top ring 221 to the polishing positions LP1 to LP4 on the polishing table 220 and pressing the wafer W against the polishing surface of the polishing pad 2200 to which the polishing fluid has been supplied from the polishing fluid supply nozzle 222a, the wafer W is polished. When the polishing processing PP ends, the top ring 221 moves to the polishing unit handover positions LT1 to LT4 and hands over the wafer W after the polishing processing to the second transport units 241A and 241B.

### (Finishing Part)

The finishing part 23 includes a plurality (in this embodiment, six with three types each arranged in upper and lower (two) stages) of finishing units 230A to 232A and 230B to 232B that respectively perform a finishing processing PC on the wafer W. In this embodiment, the first to third finishing units 230A to 232A are arranged in the upper stage side by side along the long-side direction of the housing 20, and the first to third finishing units 230B to 232B having the same configuration are arranged in the lower stage side by side along the long-side direction of the housing 20. The first to third finishing units 230A to 232A and 230B to 232B respectively perform the finishing processing PC in their arrangement sequence (finishing process sequence) at finishing positions LC1 to LC3.

As the finishing processing PC of a most upstream process, the first finishing units 230A and 230B perform a roll sponge washing processing (first finishing processing PC1) of washing the wafer W after the polishing processing using a roll sponge 2300 during a first finishing processing time TC1. The second finishing units 231A and 231B perform a pen sponge washing processing (second finishing processing PC2) of washing the wafer W after the roll sponge washing processing using a pen sponge 2310 during a second finishing processing time TC2. As the finishing processing PC of a most downstream process, the third finishing units 232A and 232B perform a drying processing (third finishing processing PC3) of drying the wafer W after the pen sponge washing processing during a third finishing processing time TC3. The finishing processing PC may also start with, for example, the pen sponge washing processing, omitting the roll sponge washing processing.

The roll sponge 2300 and the pen sponge 2310 are formed of synthetic resin such as PVA and nylon and have a porous structure. The roll sponge 2300 and the pen sponge 2310 function as washing tools for scrubbing and washing the wafer W and are replaceably attached to the first finishing units 230A and 230B and the second finishing units 231A and 231B, respectively.

Instead of or in addition to any of the first and second finishing units 230A, 230B, 231A, and 231B, the finishing part 23 may also include a finishing unit (not shown) that performs a buff washing processing of washing the wafer W using a buff, and any of the first and second finishing units 230A, 230B, 231A, and 231B may be omitted. Further, in this embodiment, although the first to third finishing units 230A to 232A and 230B to 232B have been described as holding the wafer W in a horizontal position (horizontal holding), they may also hold the wafer W in a vertical or oblique position.

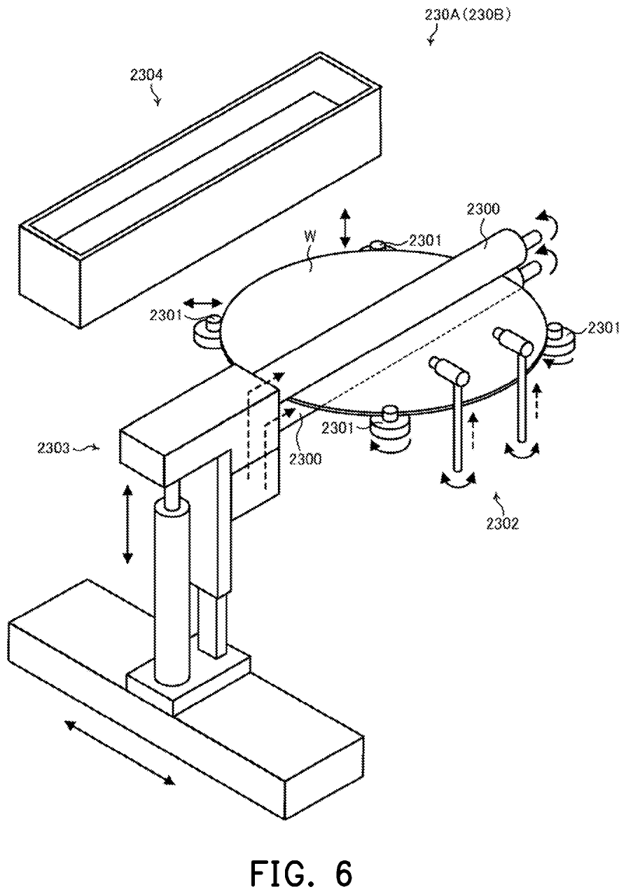

FIG. 6 is a perspective view showing an example of the first finishing units 230A and 230B which perform the roll sponge washing processing. The first finishing units 230A and 230B include a substrate holding part 2301 that holds the wafer W, a washing fluid supply part 2302 that supplies a substrate washing fluid to the wafer W, a substrate washing part 2303 that rotatably supports the roll sponge 2300 and causes the roll sponge 2300 to contact the wafer W to wash the wafer W, and a washing tool washing part 2304 that washes (self-cleans) the roll sponge 2300 with a washing tool washing fluid. The substrate washing fluid may be any of pure water (rinse liquid) and a chemical solution, and may be a liquid or a two-fluid mixture of a liquid and a gas, or may contain a solid such as dry ice. The washing tool washing fluid may be any of pure water (rinse liquid) and a chemical solution.

In the roll sponge washing processing performed by the first finishing units 230A and 230B, the wafer W is rotated in a state held at the first finishing position LC1 by the substrate holding part 2301. Then, with the substrate washing fluid supplied to the washed surface of the wafer W from the washing fluid supply part 2302, the wafer W is washed by slidably contacting the roll sponge 2300, which is rotated around its axis by the substrate washing part 2303, with the washed surface of the wafer W.

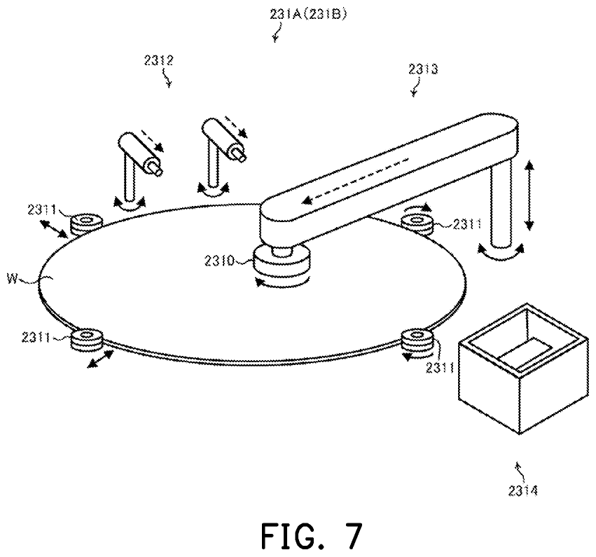

FIG. 7 is a perspective view showing an example of the second finishing units 231A and 231B which perform the pen sponge washing processing. The second finishing units 231A and 231B include a substrate holding part 2311 that holds the wafer W, a washing fluid supply part 2312 that supplies a substrate washing fluid to the wafer W, a substrate washing part 2313 that rotatably supports the pen sponge 2310 and causes the pen sponge 2310 to contact the wafer W to wash the wafer W, and a washing tool washing part 2314 that washes (self-cleans) the pen sponge 2310 with a washing tool washing fluid.

In the pen sponge washing processing performed by the second finishing units 231A and 231B, the wafer W is rotated in a state held at the second finishing position LC2 by the substrate holding part 2311. Then, with the substrate washing fluid supplied to the washed surface of the wafer W from the washing fluid supply part 2312, the wafer W is washed by slidably contacting the pen sponge 2310, which is rotated around its axis by the substrate washing part 2313, with the washed surface of the wafer W.

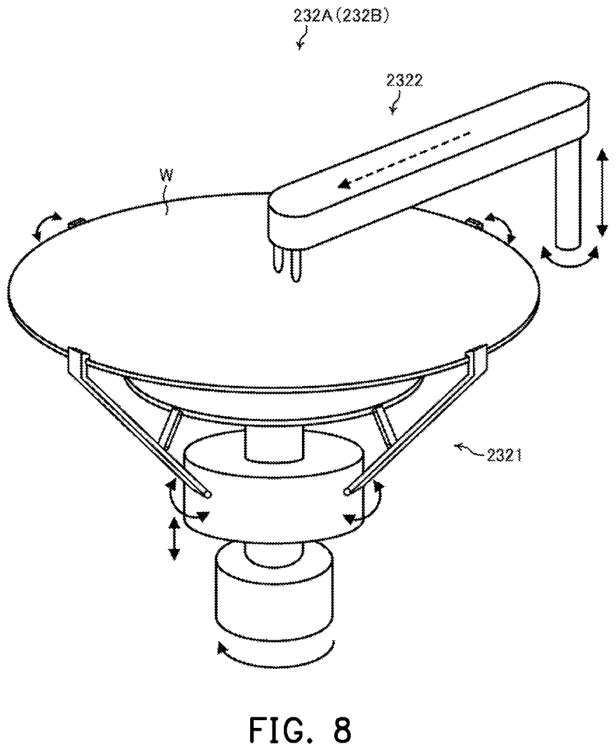

FIG. 8 is a perspective view showing an example of the third finishing units 232A and 232B which perform the drying processing. The third finishing units 232A and 232B include a substrate holding part 2321 that holds the wafer W, and a drying fluid supply part 2322 that supplies a substrate drying fluid to the wafer W. The substrate drying fluid is, for example, IPA vapor and pure water (rinse liquid), and may be a liquid or a two-fluid mixture of a liquid and a gas, or may contain a solid such as dry ice.

In the drying processing performed by the third finishing units 232A and 232B, the wafer W is rotated in a state held at the third finishing position LC3 by the substrate holding part 2321.

Then, with the substrate drying fluid supplied to the washed surface of the wafer W from the drying fluid supply part 2322, the drying fluid supply part 2322 is moved to the lateral edge side (radially outer side) of the wafer W. Afterward, the wafer W is dried by being rotated at high speed.

### (Substrate Transport Part)

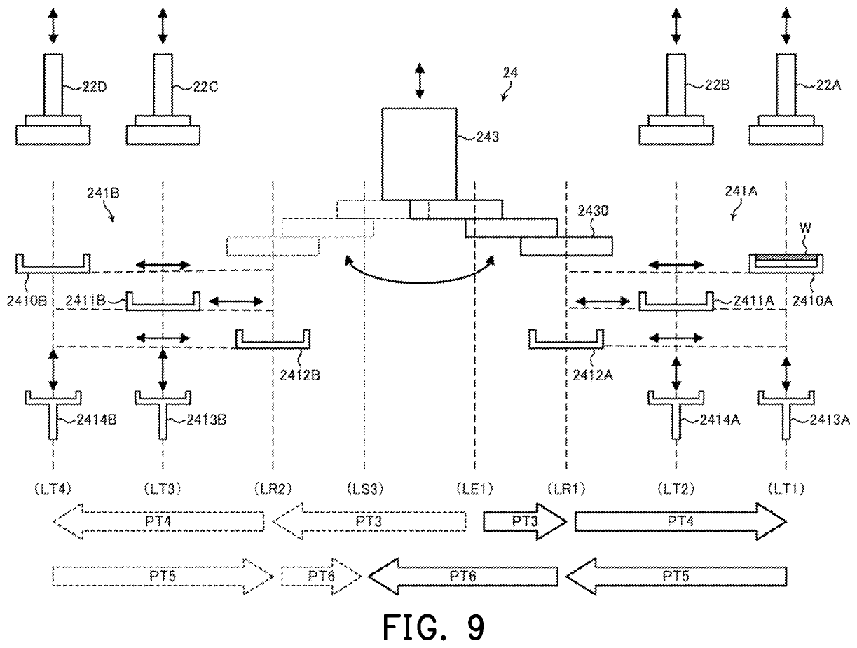

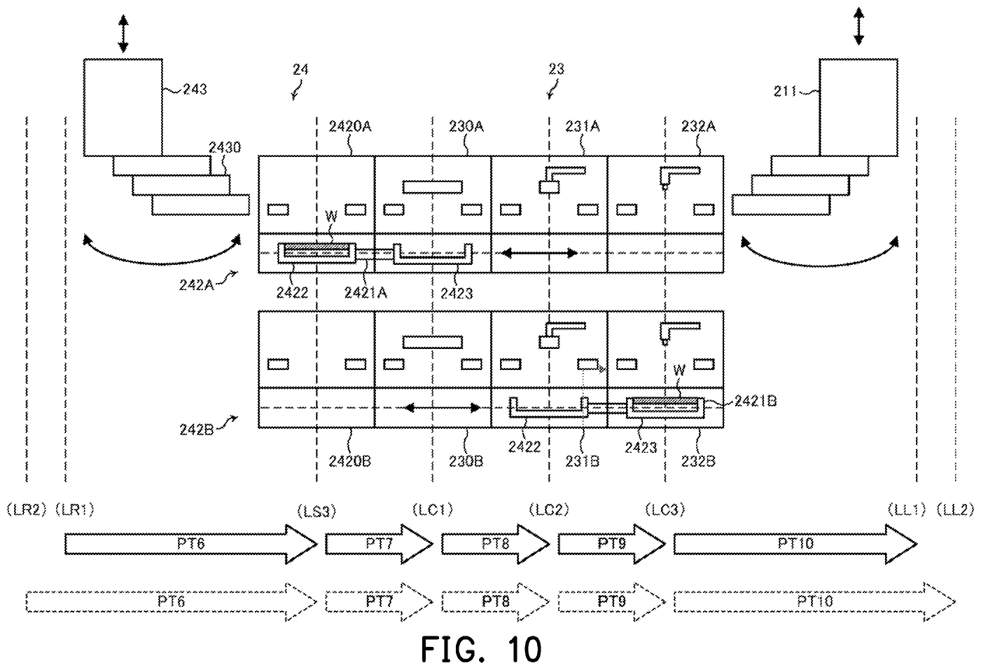

FIG. 9 is a schematic side view showing an example of the substrate transport part 24 (second transport units 241A and 241B and transfer robot 243). FIG. 10 is a schematic side view showing an example of the substrate transport part 24 (third transport units 242A and 242B and transfer robot 243). The substrate transport part 24 is composed of a plurality of transport processing units in which a transport route of the time when transporting the substrate in the transport processing may be selected.

As shown in FIG. 2, the substrate transport part 24 includes a first transport unit 240, second transport units 241A and 241B, third transport units 242A and 242B, and a transfer robot 243. In this embodiment, the second transport unit includes a second transport unit 241A arranged on the first and second polishing unit 22A and 22B side (hereinafter referred to as a “right side”), and a second transport unit 241B arranged on the third and fourth polishing unit 22C and 22D side (hereinafter referred to as a “left side”). Further, the third transport unit includes a third transport unit 242A arranged in the upper stage and a third transport unit 242B arranged in the lower stage.

The first transport unit 240 is arranged between the polishing part 22 and the finishing part 23, and is configured to be movable in the horizontal direction between a first transport start position LS1 and a first transport end position LE1 along the long-side direction of the housing 20.

As the transport processing PT on the wafer W, the first transport unit 240 performs a pre-polishing transport processing PT2 of transporting a wafer W before the polishing processing, which is supplied by the supply discharge robot 211, from the first transport start position LS1 to the first transport end position LE1.

The second transport units 241A and 241B are arranged on the polishing part 22 side and are configured to be movable in the horizontal direction along the long-side direction of the housing 20 and movable in the up-down direction.

The right-side second transport unit 241A includes a plurality (in this embodiment, three arranged in three stages in the up-down direction) of transport mechanisms 2410A to 2412A that move in the horizontal direction independently of each other between a transfer robot handover position LR1 and the polishing unit handover positions LT1 and LT2, a first pusher mechanism 2413A that is arranged at the polishing unit handover position LT1 and moves in the up-down direction, and a second pusher mechanism 2414A that is arranged at the polishing unit handover position LT2 and moves in the up-down direction.

The left-side second transport unit 241B includes a plurality (in this embodiment, three arranged in three stages in the up-down direction) of transport mechanisms 2410B to 2412B that move in the horizontal direction independently of each other between a transfer robot handover position LR2 and the polishing unit handover positions LT3 and LT4, a first pusher mechanism 2413B that is arranged at the polishing unit handover position LT3 and moves in the up-down direction, and a second pusher mechanism 2414B that is arranged at the polishing unit handover position LT4 and moves in the up-down direction.

As the transport processing PT on the wafer W, each of the plurality of transport mechanisms 2410A to 2412A and 2410B to 2412B in the second transport units 241A and 241B performs a pre-polishing transport-in processing PT4 of transporting the wafer W before the polishing processing from the transfer robot handover positions LR1 and LR2 to the polishing unit handover positions LT1 to LT4, and a post-polishing transport-out processing PT5 of transporting the wafer W after the polishing processing from the polishing unit handover positions LT1 to LT4 to the transfer robot handover positions LR1 and LR2.

The third transport units 242A and 242B are arranged on the finishing part 23 side and are configured to be movable in the horizontal direction between a third transport start position LS3, the first finishing position LC1, the second finishing position LC2, and the third finishing position LC3 along the long-side direction of the housing 20.

The upper-stage third transport unit 242A includes a wafer station 2420A that holds the wafer W after the polishing processing and at which the wafer W is capable of standing by, and a transport mechanism 2421A that moves in the horizontal direction between the wafer station 2420A and the first to third finishing units 230A to 232A. The lower-stage third transport unit 242B includes a wafer station 2420B that holds the wafer W after the polishing processing and at which the wafer W is capable of standing by, and a transport mechanism 2421B that moves in the horizontal direction between the wafer station 2420B and the first to third finishing units 230B to 232B. The transport mechanisms 2421A and 2421B include a pair of left and right hands 2422 and 2423 for handing over the wafer W. One hand 2422 is used when handing over the wafer W after the polishing processing and before the finishing processing, and the other hand 2423 is used when handing over the wafer W after the finishing processing. For example, the hands 2422 and 2423 are configured to be capable of extending and flipping the wafer W upside down.

As the transport processing PT on the wafer W, the transport mechanisms 2421A and 2421B in the third transport units 242A and 242B perform a post-polishing transport processing PT7 of transporting the wafer W after the polishing processing from the third transport start position LS3 to the finishing part 23 (in this embodiment, the first finishing position LC1 of the first finishing units 230A and 230B), and during-finishing transport processings PT8 and PT9 of transporting the wafer W during the finishing processing between each finishing unit. In this embodiment, as the during-finishing transport processing, the third transport units 242A and 242B perform a first during-finishing transport processing PT8 of transporting the wafer W during the finishing processing from the first finishing units 230A and 230B (first finishing position LC1) to the second finishing units 231A and 231B (second finishing position LC2), and a second during-finishing transport processing PT9 of transporting the wafer W during the finishing processing from the second finishing units 231A and 231B (second finishing position LC2) to the third finishing units 232A and 232B (third finishing position LC3).

The transfer robot 243 is configured to be movable in the up-down direction and movable in the turning direction. The transfer robot 243 includes a hand 2430 for handing over the wafer W. For example, the hand 2430 is configured to be extendable and capable of flipping the wafer W upside down.

As the transport processing PT on the wafer W, the transfer robot 243 performs a pre-polishing transport processing PT3 of receiving the wafer W before the polishing processing from the first transport unit 240 at the first transport end position LE1 and handing over the wafer W to the second transport units 241A and 241B at the transfer robot handover positions LR1 and LR2, and a post-polishing transport processing PT6 of receiving the wafer W after the polishing processing from the second transport units 241A and 241B at the transfer robot handover positions LR1 and LR2 and handing over the wafer W to the third transport units 242A and 242B at the third transport start position LS3.

### (Control Unit)

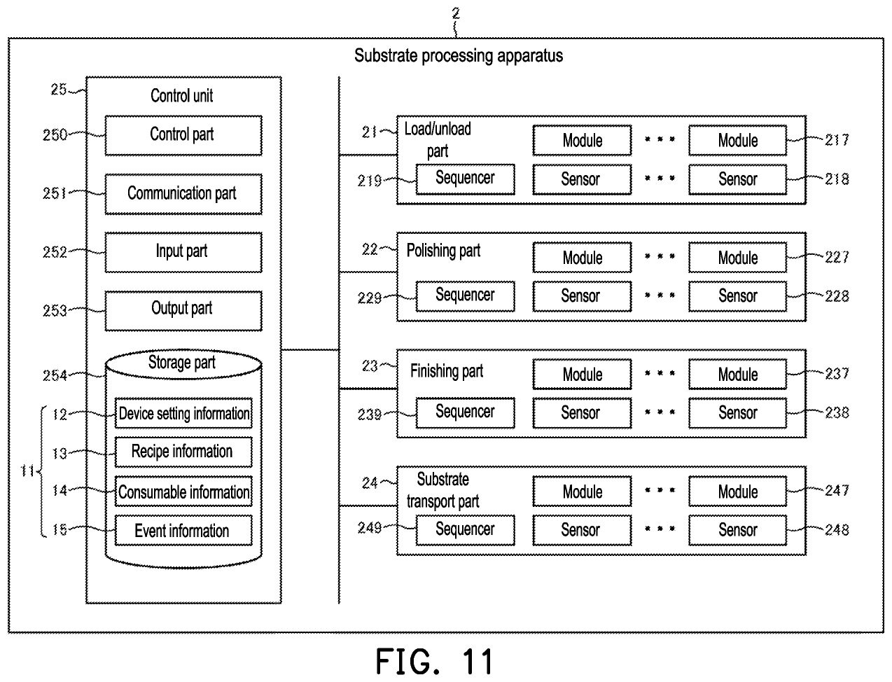

FIG. 11 is a block diagram showing an example of the substrate processing apparatus 2. The control unit 25 is electrically connected to each part 21 to 24 and functions as a control part that comprehensively controls each part 21 to 24. Hereinafter, a control system (modules, sensors, and sequencers) of the polishing part 22, the finishing part 23, and the substrate transport part 24 will be described as an example. Since the basic configuration and function of the load/unload part 21 are also common with the other parts, descriptions thereof will be omitted.

The polishing part 22 includes a plurality of modules 227 that are arranged respectively at each substrate processing unit (in this embodiment, the first to fourth polishing units 22A to 22D) and serve as control targets, a plurality of sensors 228 that are arranged respectively at the plurality of modules 227 and detect data (detection values) necessary for the control on each module 227, and a sequencer 229 that controls the action of each module 227 based on the detection value of each sensor 228.

The finishing part 23 includes a plurality of modules 237 that are arranged respectively at each substrate processing unit (in this embodiment, the first to third finishing units 230A to 232A and 230B to 232B) and serve as control targets, a plurality of sensors 238 that are arranged respectively at the plurality of modules 237 and detect data (detection values) necessary for the control on each module 237, and a sequencer 239 that controls the action of each module 237 based on the detection value of each sensor 238.

The substrate transport part 24 includes a plurality of modules 247 that are arranged respectively at each transport processing unit (in this embodiment, the first transport unit 240, the second transport units 241A and 241B, the third transport units 242A and 242B, and the transfer robot 243) and serve as control targets, a plurality of sensors 248 that are arranged respectively at the plurality of module 247 and detect data (detection values) necessary for the control on each module 247, and a sequencer 249 that controls the action of each module 247 based on the detection value of each sensor 248.

The modules 227, 237, and 247 include a rotating motor, a linear motor, an air actuator, a hydraulic actuator, etc., provided at each part, and perform rotational motion and linear motion. In the modules 227, 237, and 247, driving force transmission mechanisms such as linear guides, ball screws, gears, belts, couplings, bearings, etc., are combined as appropriate according to the function of each part. Further, the sensors 228, 238, and 248 include, for example, a linear sensor, an encoder sensor, a limit sensor, a torque sensor, an acceleration sensor, an angular velocity sensor, a current sensor, a flow rate sensor, a pressure sensor, a vibration sensor, a temperature sensor, a proximity sensor, etc.

The control unit 25 includes a control part 250, a communication part 251, an input part 252, an output part 253, and a storage part 254. For example, the control unit 25 is composed of a general-purpose or dedicated computer (see FIG. 12 to be described later).

The communication part 251 is connected to the network 7 and functions as a communication interface for sending and receiving various data. The input part 252 receives various input operations. The output part 253 functions as a user interface by outputting various information via a display screen, signal tower lighting, and buzzer sounds.

The storage part 254 stores various programs (operating system (OS), control programs, application programs, web browsers, etc.) and data (the device information 11 and the like) to be used in the action of the substrate processing apparatus 2.

The control part 250 acquires detection values of the plurality of sensors 218, 228, 238, and 248 (hereinafter referred to as a “sensor group”) via the plurality of sequencers 219, 229, 239, and 249 (hereinafter referred to as a “sequencer group”), and causes the plurality of modules 217, 227, 237, and 247 (hereinafter referred to as a “module group”) to act in cooperation. Then, the substrate processing apparatus 2 performs an automatic operation by controlling each part 21 to 24 with the control part 250 and sequentially performing the polishing processing PP, the finishing processing PC, the transport processing PT, etc. on a plurality of wafers W in the wafer cassette.

The device information 11 includes, for example, device setting information 12, recipe information 13, consumable information 14, event information 15, etc. The device information 11 is displayed via the display screen and is data editable by the operator.

The device setting information 12 is information that defines the action content of the substrate processing apparatus 2 of the time when a processing action (automatic operation) repeating the substrate processing and the transport processing on the plurality of wafers W is performed in the substrate processing apparatus 2. The device setting information 12 has a plurality of device setting items, and the action content of the substrate processing apparatus 2 is defined by setting a setting value respectively for each of the plurality of device setting items.

The device setting items include, for example, a coordinate value, a moving speed, a moving acceleration, a timer time, etc. of each transport processing unit. Further, the device setting items include a coordinate value, a moving speed, a moving acceleration, a timer time, etc. of each substrate processing unit (in this embodiment, the polishing units 22A to 22D and the finishing units 230A to 232A and 230B to 232B). The device setting items may also include a version of the control program for controlling the action of the substrate processing apparatus 2.

The recipe information 13 is information indicating processing contents of the polishing processing PP and the finishing processing PC. The recipe information 13 has a plurality of recipe setting items, and the processing contents of the polishing processing PP and the finishing processing PC are defined by setting a setting value respectively for each of the plurality of recipe setting items. The recipe information 13 may be set for each one wafer W or may be set for each plurality of wafers W constituting a lot.

The recipe setting items of the polishing processing PP include, for example, a table rotation speed of the polishing table 220, a top ring pressing time of the top ring 221, a wafer pressing load, a wafer rotation speed, a supply amount of the polishing fluid supplied by the polishing fluid supply part 222, a supply timing, a dresser action time of the dresser 223, an atomizer action time of the atomizer 224, etc.

The recipe setting items of the finishing processing PC include, for example, a roll sponge action time, a roll sponge rotation speed, a wafer rotation speed, a supply amount and a supply timing of the substrate washing fluid in the roll sponge washing processing (first finishing processing PC1), a pen sponge action time, a pen sponge rotation speed, a wafer rotation speed, a supply amount and a supply timing of the substrate washing fluid in the pen sponge washing processing (second finishing processing PC2), a drying action time, a wafer rotation speed, a supply amount and a supply timing of the substrate drying fluid in the drying processing (third finishing processing PC3), etc.

The consumable information 14 is information that defines, for each consumable item, a consumption status of a consumable used in the substrate processing apparatus 2 when the processing action is performed. The consumables include, for example, the polishing pad 2200, the roll sponge 2300, the pen sponge 2310, etc. but are not limited thereto. The consumable items include, for example, a use count, a use time, and a pressure during use of the polishing pad 2200, a use count, a use time, and a pressure during use of the roll sponge 2300, and a use count, a use time, and a pressure during use of the pen sponge 2310, etc.

The event information 15 is information that defines, for each event item, a content of an event that occurs in the substrate processing apparatus 2 when the processing action is performed. The event items include, for example, an occurrence event ID, an occurrence unit ID, etc. but are not limited thereto. The occurrence event ID specifies, by an event ID, a type (e.g., defective action of an actuator, abnormality detection of a sensor, etc.) and a degree (e.g., an abnormal stop, a warning operation, etc.) of the event that occurs in the substrate processing apparatus 2. The occurrence unit ID specifies, by a unit ID, the unit at which the event occurs.

### (Hardware Configuration of Each Device)

FIG. 12 is a hardware configuration view showing an example of a computer 900. The control unit 25 of the substrate processing apparatus 2, the database device 3, the machine learning device 4, the information processing device 5A, and the user terminal device 6 are each composed of a general-purpose or dedicated computer 900.

As shown in FIG. 12, the computer 900 includes, as main components, a bus 910, a processor 912, a memory 914, an input device 916, an output device 917, a display device 918, a storage device 920, a communication interface (I/F) part 922, an external device I/F part 924, an input/output (I/O) device I/F part 926, and a media input/output part 928. These components may be omitted as appropriate depending on the use of the computer 900.

The processor 912 is composed of one or more arithmetic processing devices (central processing unit (CPU), micro-processing unit (MPU), digital signal processor (DSP), graphics processing unit (GPU), neural processing unit (NPU), etc.), and acts as a control part that coordinates the entire computer 900. The memory 914 stores various data and a program 930 and is composed of, for example, a volatile memory (DRAM, SRAM, etc.) that functions as a main memory, a non-volatile memory (ROM), a flash memory, etc.

The input device 916 is composed of, for example, a keyboard, a mouse, a numeric keypad, an electronic pen, etc. and functions as an input part. The output device 917 is composed of, for example, a sound (voice) output device, a vibration device, etc. and functions as an output part. The display device 918 is composed of, for example, a liquid crystal display, an organic EL display, an electronic paper, a projector, etc. and functions as an output part. The input device 916 and the display device 918 may be integrally configured, such as a touch panel display. The storage device 920 is composed of, for example, an HDD, an SSD, etc. and functions as a storage part. The storage device 920 stores various data necessary for executing the operating system and the program 930.

The communication I/F part 922 is connected in a wired or wireless manner to a network 940 (which may be the same as the network 7 in FIG. 1) such as the Internet or an intranet, and functions as a communication part that sends and receives data to and from other computers according to a predetermined communication standard. The external device I/F part 924 is connected in a wired or wireless manner to an external device 950 such as a camera, a printer, a scanner, a reader/writer, and functions as a communication part that sends and receives data to and from the external device 950 according to a predetermined communication standard. The I/O device I/F part 926 is connected to an I/O device 960 such as various sensors and actuators, and functions as a communication part that sends and receives various signals and data, such as detection signal detected by sensors and control signals for actuators, to and from the I/O device 960. The media input/output part 928 is composed of, for example, a drive device such as a DVD drive and a CD drive, a memory card slot, and a USB connector and performs read and write of data from and to media (non-transitory storage media) 970 such as a DVD, a CD, a memory card, and a USB memory.

In the computer 900 having the above configuration, the processor 912 calls the program 930 stored in the storage device 920 to the memory 914 to execute the program 930, and controls each part of the computer 900 via the bus 910. The program 930 may be stored in the memory 914 instead of the storage device 920. The program 930 may be recorded on the media 970 in an installable file format or an executable file format and may be provided to the computer 900 via the media input/output part 928. The program 930 may also be provided to the computer 900 by downloading over the network 940 via the communication I/F part 922. Further, in the computer 900, the various functions realized by the processor 912 executing the program 930 may also be realized by hardware such as FPGA and ASIC, for example.

The computer 900 is composed of, for example, a stationary computer or a portable computer and is an electronic device of any form. The computer 900 may be a client-type computer, may be a server-type computer or a cloud-type computer, or may be, for example, an embedded-type computer called a control panel, a controller (including a microcontroller, a programmable logic controller, and a sequencer), etc. The computer 900 may also be applied to devices other than each device 2 to 6.

(Production history information 30)

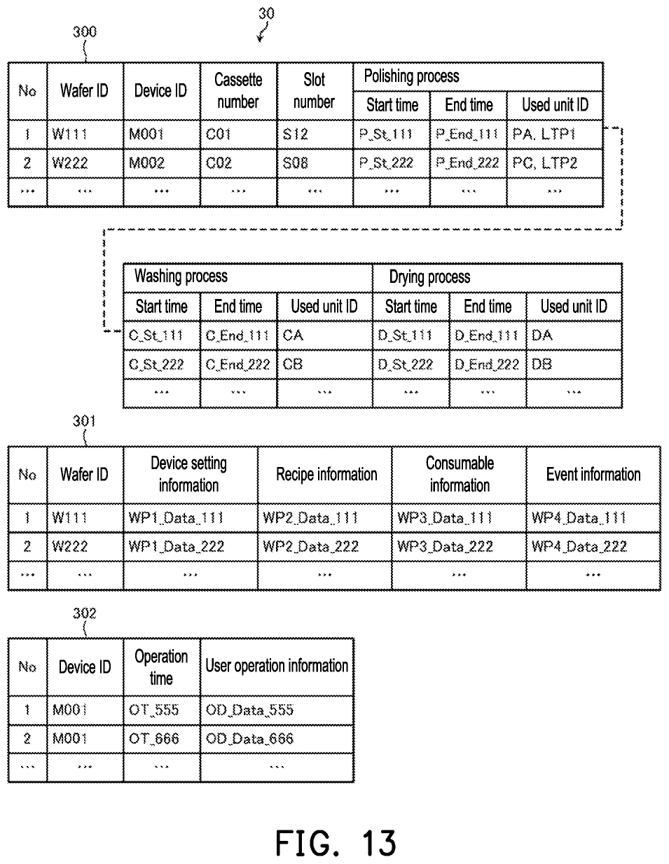

FIG. 13 is a data structure view showing an example of the production history information managed by the database device 3. The production history information 30 includes, for example, a wafer history table 300 related to the wafer W, the time of each processing, etc., a device information table 301 related to the device information 11, and an operation history table 302 related to the operation information, as tables obtained by classifying and registering the reports R acquired when the processing action is performed in the substrate processing apparatus 2 for regular production.

In each record of the wafer history table 300, for example, a wafer ID, a device ID, a cassette number, a slot number, a start time, an end time, and a used unit ID of each processing, etc. are registered. Although the polishing processing, the washing processing, and the drying processing are illustrated as an example in FIG. 13, other processings are similarly registered. The used unit ID specifies, by a unit ID, the unit used in each processing, and a unit type (e.g., a transport processing, a polishing processing, a roll sponge washing processing, a pen sponge washing processing, a drying processing, etc.) indicating the type of the unit is associated with the unit ID.

In each record of the device information table 301, for example, a wafer ID and the device setting information 12, the recipe information 13, the consumable information 14, the event information 15, etc. included in the device information 11 are registered. The device setting information 12, the recipe information 13, the consumable information 14, and the event information 15 may be registered directly or may be registered as information indicating their reference destinations.

In each record of the operation history table 302, for example, a device ID, an operation time, user operation information, etc. are registered. The user operation information includes, for example, an editing content (e.g., an edited device setting item or recipe setting item, setting values before and after editing, etc.) of the time when the operator edits the device setting information 12 and the recipe information 13. Further, the user operation information includes, for example, a replacement content (e.g., a type of a replaced consumable) of a case where the operator replaces a consumable.

In the production history information 30, by referring to the wafer history table 300, for example, a processing quantity of wafers W per unit time (hereinafter referred to as a “unit time processing quantity WPH”) of the time when a processing action is performed on a plurality of wafers W may be calculated. By referring to the device information table 301 and the operation history table 302 associated with the wafer ID and the device ID, various information of the time when the processing action is performed can be acquired.

### (Test Information 31)

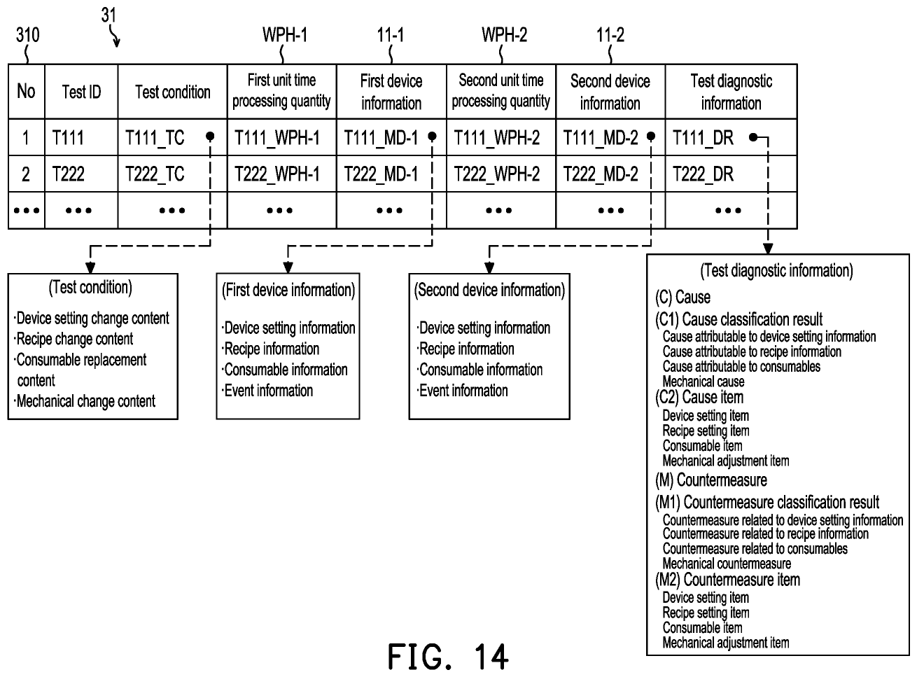

FIG. 14 is a data structure view showing an example of the test information 31 managed by the database device 3. The test information 31 includes a test table 310 in which test conditions and test results acquired when a test action is performed in a test device are classified and registered.

Each record of the test table 310 includes, for example, a test ID, a test condition, a first unit time processing quantity WPH-1, first device information 11-1, a second unit time processing quantity WPH-2, second device information 11-2, test diagnostic information, etc.

The test condition may define a condition that is changed between a first test action and a second test action when the first test action and the second test action are performed in the test device. For example, examples of the test condition include a device setting change content of the time when a setting value for a specific (or a plurality of) device setting item included in the device setting information 12 is changed, a recipe change content of the time when a setting value for a specific (or a plurality of) recipe setting item included in the recipe information 13 is changed, a consumable replacement content of the time when a specific (or a plurality of) consumable is replaced, and a mechanical change content of the time when a mechanical adjustment value (e.g., a stroke amount of an air actuator) of a specific module 217, 227, 237, and 247 is changed as a mechanical adjustment item capable of being mechanically adjusted.

In the test device, by performing the first test action before the setting value or the adjustment value in the test condition is changed or before a consumable is replaced, a unit time processing quantity WPH and device information 11 at that time are registered as the first unit time processing quantity WPH-1 and the first device information 11-1. Further, in the test device, by performing the second test action after the setting value or the mechanical adjustment value in the test condition is changed or after a consumable is replaced, a unit time processing quantity WPH and device information 11 at that time are registered as the second unit time processing quantity WPH-2 and the second device information 11-2.

The test diagnostic information includes at least one of a cause of the time when a difference occurs between the first unit time processing quantity WPH-1 and the second unit time processing quantity WPH-2, and a countermeasure for eliminating that difference. In that case, the test diagnostic information may include at least one of a cause classification result that classifies the causes into a plurality of cause types, and a countermeasure classification result that classifies the countermeasures into a plurality of countermeasure types. The cause types include at least one of a cause attributable to the device setting information 12, a cause attributable to the recipe information 13, a cause attributable to the consumables, and a mechanical cause of the substrate processing apparatus 2. The countermeasure types include at least one of a countermeasure related to the device setting information 12, a countermeasure related to the recipe information 13, a countermeasure related to the consumables, and a mechanical countermeasure of the substrate processing apparatus 2.

Further, the test diagnostic information may include at least one of a cause item specified by at least one of the device setting item, the recipe setting item, the consumable item, and the mechanical adjustment item as an item related to the cause, and a countermeasure item specified by at least one of the device setting item, the recipe setting item, the consumable item, and the mechanical adjustment item as an item related to the countermeasure.

The test diagnostic information is registered based on the test condition. For example, in the case where a device setting change content is registered as the test condition, the cause type is classified as a cause attributable to the device setting information 12, and the cause item is specified by the device setting item changed by the device setting change content. In the case where a recipe change content is registered as the test condition, the cause type is classified as a cause attributable to the recipe information 13, and the cause item is specified by the recipe setting item changed by the recipe change content. In the case where a consumable replacement content is registered as the test condition, the cause type is classified as a cause attributable to the consumables, and the cause item is specified by the consumable item changed by the consumable replacement content. In the case where a mechanical change content is registered as the test condition, the cause type is classified as a mechanical cause, and the cause item is specified by the mechanical adjustment item changed by the mechanical change content. The test diagnostic information may be inputted from the operator by receiving an input operation of the operator via the user terminal device 6.

### (Simulation Information 32)

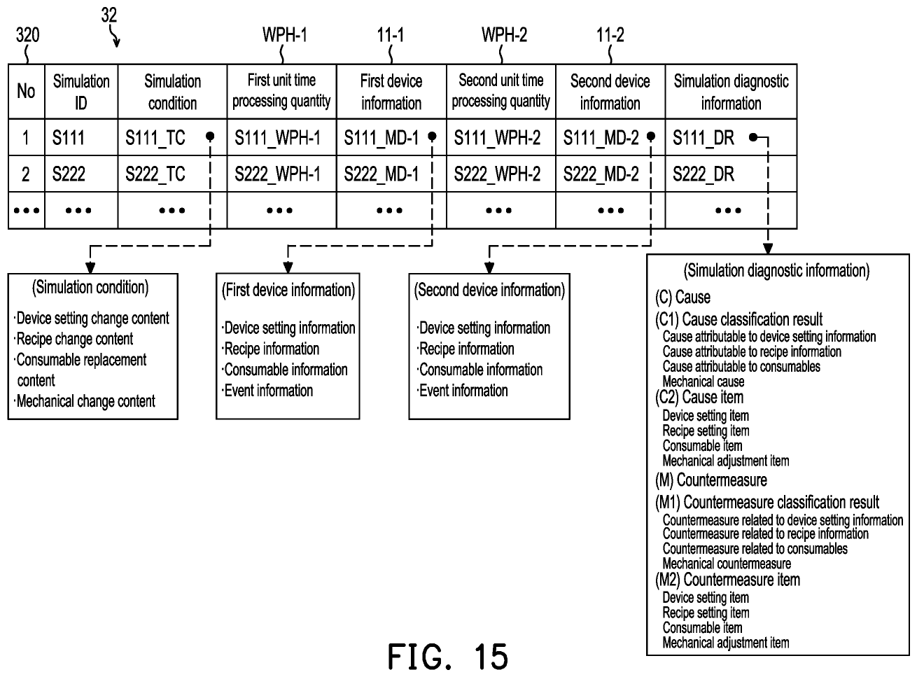

FIG. 15 is a data structure view showing an example of the simulation information 32 managed by the database device 3. The simulation information 32 includes a simulation table 320 in which simulation conditions and simulation results acquired when a simulation action is performed in the simulation device are classified and registered.

Each record of the simulation table 320 includes, for example, a simulation ID, a simulation condition, a first unit time processing quantity WPH-1, first device information 11-1, a second unit time processing quantity WPH-2, second device information 11-2, simulation diagnostic information, etc.

The simulation condition may define a condition that is changed between a first simulation action and a second simulation action when the first simulation action and the second simulation action are performed in the simulation device. Examples of the simulation condition include a device setting change content of the time when a setting value for a specific (or a plurality of) device setting item included in the device setting information 12 is changed, a recipe change content of the time when a setting value for a specific (or a plurality of) recipe setting item included in the recipe information 13 is changed, a consumable replacement content of the time when a specific (or a plurality of) consumable is replaced, and a mechanical change content of the time when a mechanical adjustment value (e.g., a stroke amount of an air actuator) of a specific module 217, 227, 237, and 247 is changed as a mechanical adjustment item capable of being mechanically adjusted.

In the simulation device, by performing the first simulation action before the setting value or the adjustment value in the simulation condition is changed or before the consumable is replaced, a unit time processing quantity WPH and device information 11 at that time are registered as the first unit time processing quantity WPH-1 and the first device information 11-1. Further, in the simulation device, by performing the second simulation action after the setting value or the mechanical adjustment value in the simulation condition is changed or after the consumable is replaced, a unit time processing quantity WPH and device information 11 at that time are registered as the second unit time processing quantity WPH-2 and the second device information 11-2.

The simulation diagnostic information includes at least one of a cause of the time when a difference occurs between the first unit time processing quantity WPH-1 and the second unit time processing quantity WPH-2, and a countermeasure for eliminating that difference. The simulation diagnostic information is registered based on the simulation condition in the same manner as the test table 310, but may also be inputted from the operator by receiving an input operation of the operator via the user terminal device 6. Since the data structure of the simulation diagnostic information is the same as the test diagnostic information in the test table 310, detailed descriptions thereof will be omitted herein.

### (Machine Learning Device 4)

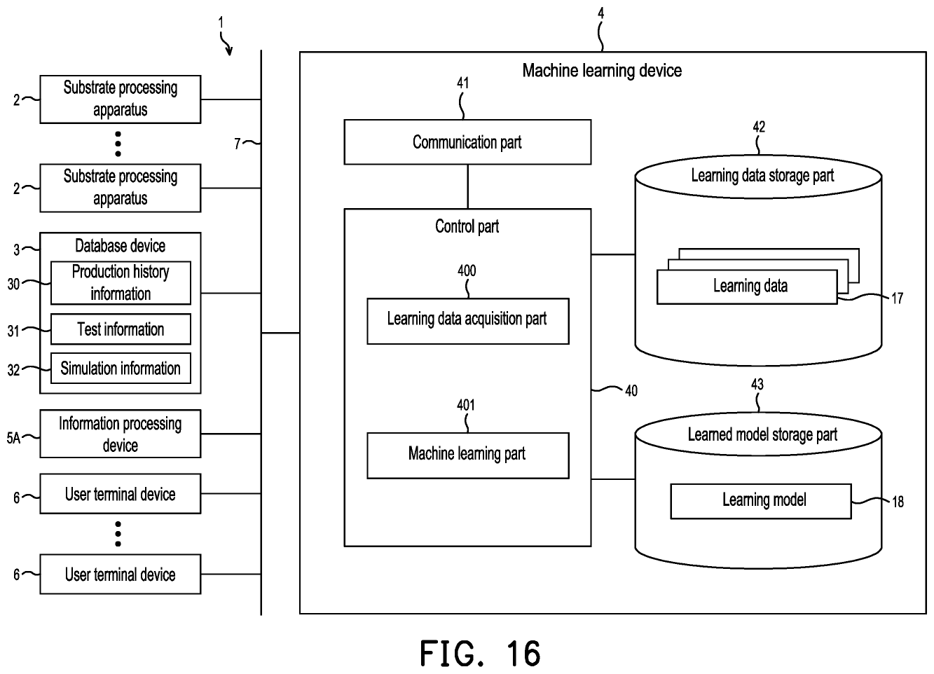

FIG. 16 is a block diagram showing an example of the machine learning device 4. The machine learning device 4 includes a control part 40, a communication part 41, a learning data storage part 42, a learned model storage part 43, an input part 44, and an output part 45.

The control part 40 functions as a learning data acquisition part 400 and a machine learning part 401. The communication part 41 is connected to external devices (e.g., the substrate processing apparatus 2, the database device 3, the information processing device 5A, the user terminal device 6, the simulation device (not shown), etc.) via the network 7 and functions as a communication interface for sending and receiving various data. The input part 44 receives various input operations, and the output part 45 functions as a user interface by outputting various information via a display screen and voices.

The learning data acquisition part 400 acquires learning data 17 composed of reference information 10-A and comparison information 10-B as input data, and diagnostic information 16 as output data. The learning data 17 is data used as teaching data (training data), validation data, and test data in supervised learning. Further, the diagnostic information 16 is data used as a correct answer label in supervised learning.

For example, the learning data acquisition part 400 acquires the learning data 17 by referring to the production history information 30, the test information 31, or the simulation information 32 of the database device 3. For example, the learning data acquisition part 400 detects, in the operation history table 302, operation times of the time when a setting value of the device setting information 12 or the recipe information 13 is changed and a consumable is replaced, and acquires, from the wafer history table 300 and the device information table 301, a unit time processing quantity WPH and device information 11 before those times as the reference information 10-A, and a unit time processing quantity WPH and device information 11 after those times as the comparison information 10-B. Then, the learning data acquisition part 400 acquires the learning data 17 by receiving diagnostic information 16 for the reference information 10-A and the comparison information 10-B as an input operation of the operator via the user terminal device 6, for example.

Further, the learning data acquisition part 400 acquires the learning data 17 by acquiring, from a specific record of the test table 310, the first unit time processing quantity WPH-1 and the first device information 11-1 as the reference information 10-A, the second unit time processing quantity WPH-2 and the second device information 11-2 as the comparison information 10-B, and the test diagnostic information as the diagnostic information 16. Furthermore, the learning data acquisition part 400 acquires the learning data 17 by acquiring, from a specific record of the simulation table 320, the first unit time processing quantity WPH-1 and the first device information 11-1 as the reference information 10-A, the second unit time processing quantity WPH-2 and the second device information 11-2 as the comparison information 10-B, and the simulation diagnostic information as the diagnostic information 16.

The learning data storage part 42 is a database that stores a plurality of sets of learning data 17 acquired by the learning data acquisition part 400. The specific configuration of the database constituting the learning data storage part 42 may be appropriately designed.

The machine learning part 401 executes machine learning using a plurality of sets of learning data 17 stored in the learning data storage part 42. That is, the machine learning part 401 generates a learned learning model 18 by inputting a plurality of sets of learning data 17 to the learning model 18 and causing the learning model 18 to learn the correlation of the reference information 10-A and the comparison information 10-B with the diagnostic information 16, included in the learning data 17.

The learned model storage part 43 is a database that stores the learned learning model 18 (specifically, adjusted weight parameter group) generated by the machine learning part 401. The learned learning model 18 stored in the learned model storage part 43 is provided to an actual system (e.g., the information processing device 5A) via the network 7, recording media, etc. In FIG. 16, although the learning data storage part 42 and the learned model storage part 43 are shown as separate storage parts, they may also be composed of one storage part.

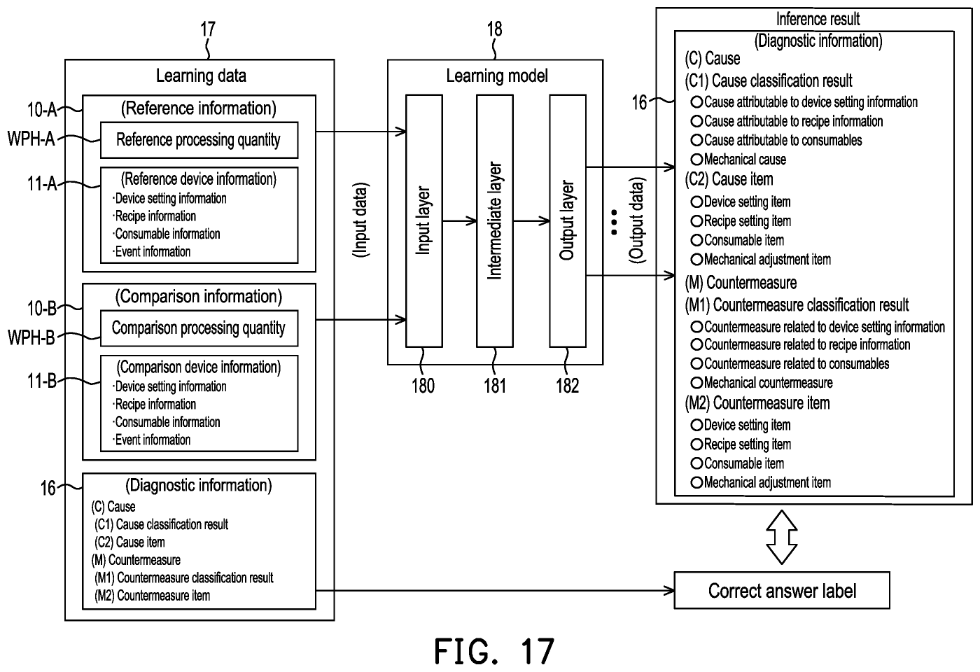

FIG. 17 is a view showing an example of the learning model 18 and the learning data 17. The learning data 17 used for machine learning of the learning model 18 is composed of the reference information 10-A and the comparison information 10-B as input data, and the diagnostic information 16 as output data.

The reference information 10-A constituting the input data of the learning data 17 includes a reference processing quantity WPH-A and reference device information 11-A.

The reference processing quantity WPH-A is a unit time processing quantity WPH of the time when a reference processing action corresponding to the processing action is performed in a reference device corresponding to a substrate processing apparatus 2 serving as a reference. In the case where the learning data acquisition part 400 acquires the learning data 17 from the test information 31 or the simulation information 32, the first unit time processing quantity WPH-1 corresponds to the reference processing quantity WPH-A.

The reference device information 11-A is device information 11 related to the reference device of the time when the reference processing action is performed. In the case where the learning data acquisition part 400 acquires the learning data 17 from the test information 31 or the simulation information 32, the first device information 11-1 corresponds to the reference device information 11-A. Similar to the first device information 11-1, the reference device information 11-A includes at least one of device setting information 12, recipe information 13, consumable information 14, and event information 15.

The comparison information 10-B constituting the input data of the learning data 17 includes a comparison processing quantity WPH-B and comparison device information 11-B.

The comparison processing quantity WPH-B is a unit time processing quantity WPH of the time when a comparison processing action corresponding to the processing action is performed in a comparison device corresponding to a substrate processing apparatus 2 serving as a comparison target of the reference device. In the case where the learning data acquisition part 400 acquires the learning data 17 from the test information 31 or the simulation information 32, the second unit time processing quantity WPH-2 corresponds to the comparison processing quantity WPH-B.

The comparison device information 11-B is device information 11 related to the comparison device of the time when the comparison processing action is performed. In the case where the learning data acquisition part 400 acquires the learning data 17 from the test information 31 or the simulation information 32, the second device information 11-2 corresponds to the comparison device information 11-B. Similar to the second device information 11-2, the comparison device information 11-B includes at least one of device setting information 12, recipe information 13, consumable information 14, and event information 15.

The diagnostic information 16 constituting the output data of the learning data 17 includes at least one of a cause of the time when a difference occurs between the reference processing quantity WPH-A and the comparison processing quantity WPH-B, and a countermeasure for eliminating the difference. That is, the diagnostic information 16 indicates the cause in the comparison device of the case where the comparison processing quantity WPH-B is less or more than the reference processing quantity WPH-A, and a countermeasure in the comparison device for bringing the comparison processing quantity WPH-B closer to the reference processing quantity WPH-A. In the case where the learning data acquisition part 400 acquires the learning data 17 from the test information 31 or the simulation information 32, the test diagnostic information and the simulation diagnostic information correspond to the diagnostic information 16.

In that case, similar to the test diagnostic information and the simulation diagnostic information, the diagnostic information 16 may include at least one of a cause classification result that classifies the causes into a plurality of cause types, and a countermeasure classification result that classifies the countermeasures into a plurality of countermeasure types. The cause types include at least one of a cause attributable to the device setting information 12, a cause attributable to the recipe information 13, a cause attributable to the consumables, and a mechanical cause of the substrate processing apparatus 2. The countermeasure types include at least one of a countermeasure related to the device setting information 12, a countermeasure related to the recipe information 13, a countermeasure related to the consumables, and a mechanical countermeasure of the substrate processing apparatus 2.

Further, the diagnostic information 16 may include at least one of a cause item specified by at least one of a device setting item, a recipe setting item, a consumable item, and a mechanical adjustment item as an item related to the cause, and a countermeasure item specified by at least one of a device setting item, a recipe setting item, a consumable item, and a mechanical adjustment items as an item related to the countermeasure. In that case, the diagnostic information 16 may indicate a plurality of cause items and countermeasure items in an order of higher relevance to the cause and the countermeasure.

The learning model 18, for example, adopts the structure of a neural network and includes an input layer 180, an intermediate layer 181, and an output layer 182. Synapses (not shown) that respectively connect each neuron are stretched between each layer, and a weight is respectively associated with each synapse. A weight parameter group composed of the weight of each synapse is adjusted by machine learning.

The input layer 180 has neurons in a quantity corresponding to the reference information 10-A and the comparison information 10-B serving as the input data, and each parameter value included in the reference information 10-A and the comparison information 10-B is inputted to each neuron, respectively. The output layer 182 has neurons in a quantity corresponding to the diagnostic information 16 serving as the output data, and a prediction result (inference result) of the diagnostic information 16 for the reference information 10-A and the comparison information 10-B is outputted as the output data.

The quantity of the learning model 18 stored in the learned model storage part 43 is not limited to one, and a plurality of learning models 18 with different conditions may be stored depending on, for example, a difference in the machine learning method or the mechanism of the substrate processing apparatus 2, types of data included in the reference information 10-A and the comparison information 10-B, types of data included in the diagnostic information 16, etc. In that case, the learning data storage part 42 may store a plurality of types of learning data 17 having data structures respectively corresponding to the plurality of learning models 18 with different conditions.

### (Machine Learning Method)

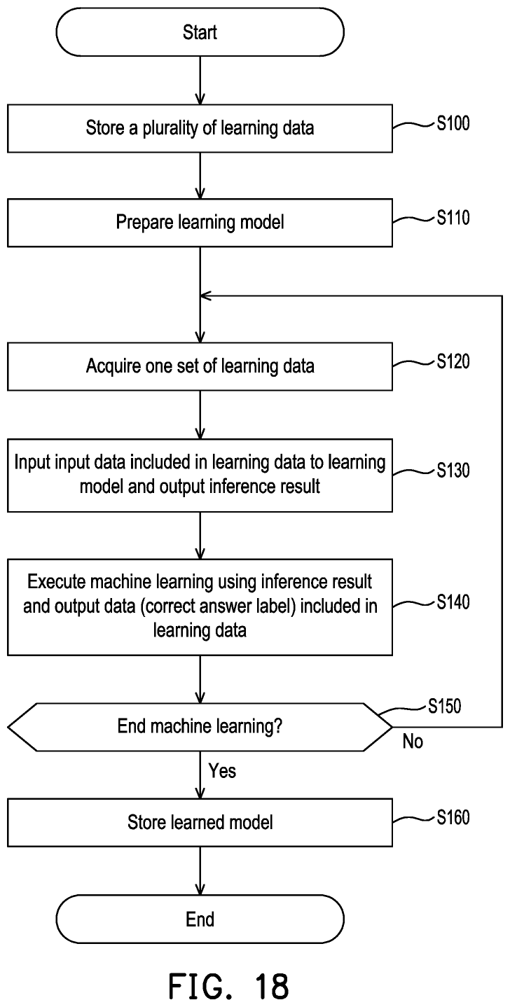

FIG. 18 is a flowchart showing an example of a machine learning method performed by the machine learning device 4.

First, in step S100, as an advance preparation for starting machine learning, the learning data acquisition part 400 acquires learning data 17 in a desired quantity and stores the acquired learning data 17 to the learning data storage part 42. The quantity of the learning data 17 prepared herein may be set considering an inference accuracy required for the learning model 18 eventually obtained.

Next, in step S110, to start machine learning, the machine learning part 401 prepares a pre-learning learning model 18. The pre-learning learning model 18 prepared herein is composed of a neural network model in which the weight of each synapse is set to an initial value.

Next, in step S120, the machine learning part 401 acquires, for example, one set of learning data 17 randomly from a plurality of sets of learning data 17 stored in the learning data storage part 42.

Next, in step S130, the machine learning part 401 inputs input data (reference information 10-A and comparison information 10-B) included in the one set of learning data 17 to the input layer 180 of the pre-learning (or during-learning) learning model 18 that has been prepared. As a result, an output data (diagnostic information 16) is outputted as an inference result from the output layer 182 of the learning model 18, but this output data has been generated by the pre-learning (or during-learning) learning model 18. Thus, in the pre-learning (or during-learning) state, the output data outputted as the inference result shows information different from the correct answer label (diagnostic information 16) included in the learning data 17.

Next, in step S140, the machine learning part 401 executes machine learning by comparing the correct answer label included in the one set of learning data 17 acquired in step S120 with the output data outputted as the inference result from the output layer 182 in step S130, and executing a processing (backpropagation) of adjusting the weight of each synapse. Accordingly, the machine learning part 401 causes the learning model 18 to learn the correlation between the input data and the output data.

Next, in step S150, the machine learning part 401 determines whether a predetermined learning end condition has been satisfied, for example, based on an evaluation value of an error function based on the correct answer label included in the learning data 17 and the output data outputted as the inference result, or based on a remaining number of the unlearned learning data 17 stored in the learning data storage part 42.

In step S150, in the case where the machine learning part 402 determines that the learning end condition has not been satisfied and machine learning is to be continued (“No” in step S150), returning to step S120, the processes of steps S120 to S140 are executed multiple times on the during-learning learning model 18 using the unlearned learning data 17. On the other hand, in step S150, in the case where the machine learning part 401 determines that the learning end condition has been satisfied and machine learning is to be ended (“Yes” in step S150), the process proceeds to step S160.

Then, in step S160, the machine learning part 401 stores, to the learned model storage part 43, the learned learning model 18 (adjusted weight parameter group) generated by adjusting the weight associated with each synapse, and ends the series of machine learning method shown in FIG. 18. In the machine learning method, step S100 corresponds to a learning data storage process, steps S110 to S150 correspond to a machine learning process, and step S160 corresponds to a learned model storage process.

As described above, according to the machine learning device 4 and the machine learning method according to this embodiment, it is possible to provide a learning model 18 capable of predicting (inferring) the diagnostic information 16 including at least one of the cause of the time when a difference occurs between the reference processing quantity WPH-A and the comparison processing quantity WPH-B and the countermeasure for eliminating that difference, from the reference information 10-A including the reference processing quantity WPH-A and the reference device information 11-A in the reference device corresponding to the substrate processing apparatus 2 serving as the reference, and the comparison information 10-B including the comparison processing quantity WPH-B and the comparison device information 11-B in the comparison device corresponding to the substrate processing apparatus 2 serving as the comparison target of the reference device.

### (Information Processing Device 5A)

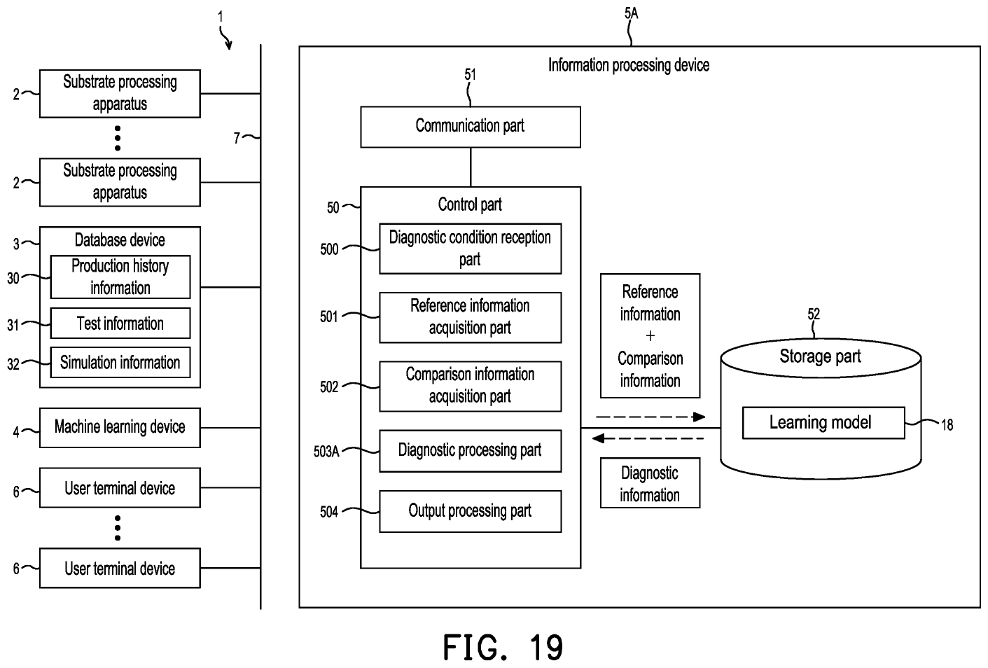

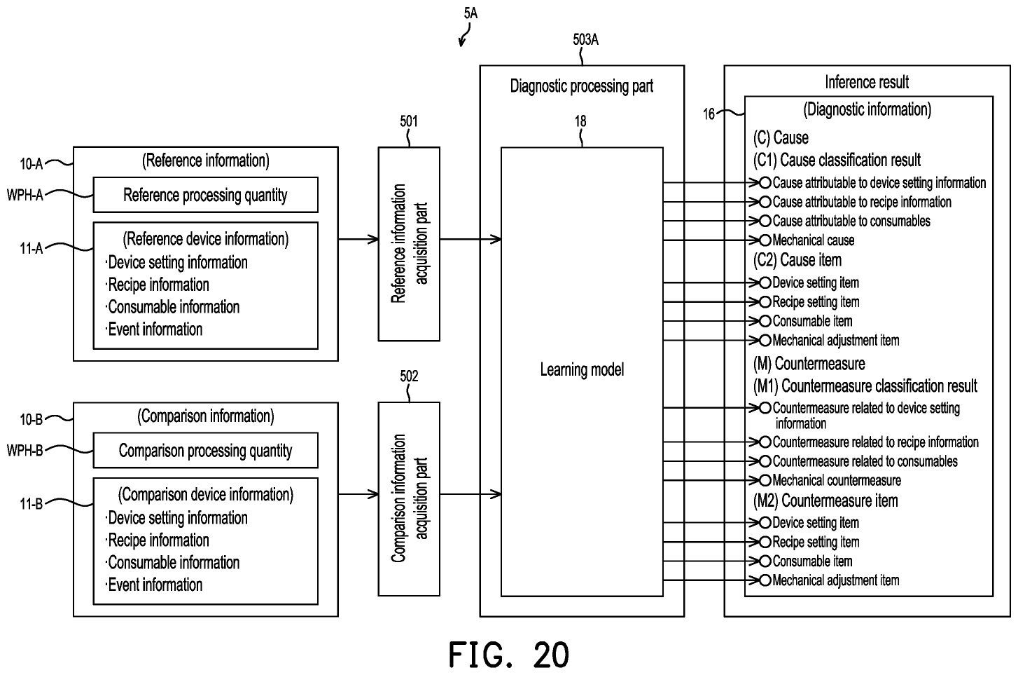

FIG. 19 is a block diagram showing an example of the information processing device 5A according to the first embodiment. FIG. 20 is a function illustrative view showing an example of the information processing device 5A according to the first embodiment. The information processing device 5A includes a control part 50, a communication part 51, and a storage part 52.

The control part 50 functions as a diagnostic condition reception part 500, a reference information acquisition part 501, a comparison information acquisition part 502, a diagnostic processing part 503A, and an output processing part 504. The communication part 51 is connected to external devices (e.g., the substrate processing apparatus 2, the database device 3, the machine learning device 4, the user terminal device 6, etc.) via the network 7 and functions as a communication interface for sending and receiving various data. The storage part 52 stores various programs (e.g. an operating system, an information processing program, etc.) and data (e.g., the learning model 18) to be used in the action of the information processing device 5A.

The diagnostic condition reception part 500 receives a diagnostic condition of the time when diagnosing the state of the substrate processing apparatus 2. For example, the diagnostic condition includes a reference device designation condition and a comparison device designation condition. For example, the diagnostic condition reception part 500 displays a display screen for inputting the diagnostic condition on the user terminal device 6, and receives the diagnostic condition according to an input operation of the operator on the display screen. The diagnostic condition reception part 500 may also automatically receive a pre-set diagnostic condition each predetermined time or each processing quantity of wafers.

The reference device designation condition specifies a reference device corresponding to a substrate processing apparatus 2 serving as a reference, and a reference processing action performed in the reference device. The reference device designation condition is designated, for example, by (A1) a combination of a device ID and a date/time, (A2) a combination of a device ID and a wafer ID, (A3) a test ID, (A4) a simulation ID, etc.

The comparison device designation condition specifies a comparison device corresponding to a substrate processing apparatus 2 serving as a comparison target of the reference device, and a comparison processing action performed in the comparison device. The comparison device designation condition is designated, for example, by (B1) a combination of a device ID and a date/time, (B2) a combination of a device ID and a wafer ID, (B3) a test ID, (B4) a simulation ID, etc.

Thus, various diagnoses can be realized according to the reference device designation condition and the comparison device designation condition. For example, in a shipping inspection at the assembly plant of the substrate processing apparatus 2, an inspection test at the production line, etc., a substrate processing apparatus 2 (or a plurality of substrate processing apparatuses 2) that is in line with the design specification of the substrate processing apparatus 2 may be designated as the reference device with (A3) or (A4) above, and a substrate processing apparatus 2 serving as an inspection target may be designated as the comparison device with (B1) or (B2) above, to perform the shipping inspection or the inspection test corresponding to an occurrence condition of an actual action error. In that case, a substrate processing apparatus 2 (or a plurality of substrate processing apparatuses 2) that has passed the inspection or a substrate processing apparatus 2 that is in line with the design specification of the substrate processing apparatus 2 may be designated as the reference device with (A1) or (A2) above. Further, in the case of confirming an over-time change in the substrate processing apparatus 2, for example, the over-time change may be confirmed by designating the substrate processing apparatus 2 (or the plurality of substrate processing apparatuses 2) in the past as the reference device with (A1) or (A2) above, and designating the substrate processing apparatus 2 of the present time as the comparison device with (B1) or (B2) above. Furthermore, in the case of evaluating the accuracy of a test device or a simulation device, for example, the accuracy of the test device or the simulation device may be evaluated by designating a substrate processing apparatus 2 (or a plurality of substrate processing apparatuses 2) that is in line with the design specification of the substrate processing apparatus 2 as the reference device with (A1) or (A2) above, and designating the test device or the simulation device serving as the evaluation target as the comparison device with (B3) or (B4) above. In the case where a plurality of substrate processing apparatuses 2 are designated as the reference device, the reference information 10-A may be acquired using an arithmetic processing of a mean, a maximum value, a minimum value, etc. on the plurality of substrate processing apparatuses 2.

The reference information acquisition part 501 acquires, as the reference information 10-A, the reference processing quantity WPH-A of the time when the reference processing action is performed in the reference device and the reference device information 11-A related to the reference device of the time when the reference processing action is performed. That is, the reference information 10-A includes the reference processing quantity WPH-A and the reference device information 11-A. The reference information acquisition part 501 acquires the reference information 10-A, for example, by referring to the production history information 30, the test information 31, or the simulation information 32 of the database device 3 based on the reference device designation condition in the diagnostic condition received by the diagnostic condition reception part 500.

The comparison information acquisition part 502 acquires, as the comparison information 10-B, the comparison processing quantity WPH-B of the time when the comparison processing action is performed in the comparison device and the comparison device information 11-B related to the comparison device of the time when the comparison processing action is performed. That is, the comparison information 10-B includes the comparison processing quantity WPH-B and the comparison device information 11-B. The comparison information acquisition part 502 acquires the comparison information 10-B, for example, by referring to the production history information 30, the test information 31, or the simulation information 32 of the database device 3 based on the comparison device designation condition in the diagnostic condition received by the diagnostic condition reception part 500.

The diagnostic processing part 503A generates diagnostic information 16 that includes at least one of the cause of the time when a difference occurs between the reference processing quantity WPH-A and the comparison processing quantity WPH-B and the countermeasure for eliminating the difference, based on the reference information 10-A acquired by the reference information acquisition part 501 and the comparison information 10-B acquired by the comparison information acquisition part 502.

In this embodiment, the diagnostic processing part 503A generates the diagnostic information 16 for the reference information 10-A and the comparison information 10-B by inputting, to the learning model 18, the reference information 10-A acquired by the reference information acquisition part 501 and the comparison information 10-B acquired by the comparison information acquisition part 502. The diagnostic information 16 may include at least one of a cause classification result and a countermeasure classification result, and may include at least one of a cause item and a countermeasure item. In that case, the diagnostic information 16 may indicate a plurality of cause items and countermeasure items in an order of higher relevance to the cause and the countermeasure.

The storage part 52 stores a learned learning model 18 to be used in the diagnostic processing part 503A. The quantity of the learning model 18 stored in the storage part 52 is not limited to one, and a plurality of learned models with different conditions may be stored and selectively or parallelly used depending on, for example, a difference in the machine learning method and the mechanism of the substrate processing apparatus 2, types of data included in the reference information 10-A and the comparison information 10-B, types of data included in the diagnostic information 16, etc. The storage part 52 may be replaced with a storage part of an external computer (e.g., a server-type computer or a cloud-type computer), and in that case, the diagnostic processing part 503A may access the external computer.

The output processing part 504 performs an output processing for outputting the diagnostic information 16 generated by the diagnostic processing part 503A. For example, with the output processing part 504 sending the diagnostic information 16 to the user terminal device 6, a display screen based on the diagnostic information 16 is displayed by the user terminal device 6. The output processing part 504 may also store the diagnostic information 16 to the storage part 52.

### (Information Processing Method)

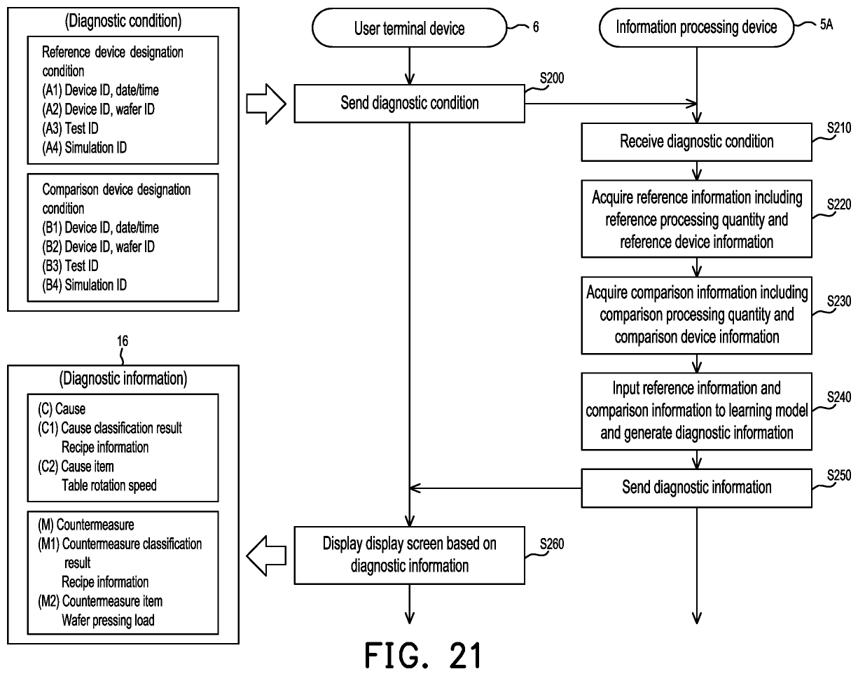

FIG. 21 is a flowchart showing an example of an information processing method performed by the information processing device 5A according to the first embodiment. Hereinafter, an action example of the case where an operator operates the user terminal device 6 to diagnose the state of a specific substrate processing apparatus 2 will be described.

First, in step S200, as the operator performs an input operation of inputting a diagnostic condition to the user terminal device 6, the user terminal device 6 sends the diagnostic condition to the information processing device 5A.

Next, in step S210, the diagnostic condition reception part 500 of the information processing device 5A receives the diagnostic condition sent in step S200.

Next, in step S220, the reference information acquisition part 501 acquires reference information 10-A including a reference processing quantity WPH-A and reference device information 11-A by referring to the production history information 30, the test information 31, or the simulation information 32 of the database device 3 based on a reference device designation condition in the diagnostic condition received in step S210.

Next, in step S230, the comparison information acquisition part 502 acquires comparison information 10-B including a comparison processing quantity WPH-B and comparison device information 11-B by referring to the production history information 30, the test information 31, or the simulation information 32 of the database device 3 based on a comparison device designation condition in the diagnostic condition received in step S210.

Next, in step S240, the diagnostic processing part 503A generates, as output data, diagnostic information 16 for the reference information 10-A and the comparison information 10-B by inputting, to the learning model 18, the reference information 10-A acquired in step S220 and the comparison information 10-B acquired in step S230 as input data, and diagnoses a state of the comparison device with respect to the reference device.

Next, in step S250, as an output processing for outputting the diagnostic information 16 generated in step S240, the output processing part 504 sends the diagnostic information 16 to the user terminal device 6. The transmission destination of the diagnostic information 16 may also be the database device 3 in addition to or instead of the user terminal device 6.

Then, in step S260, in response to the sending processing in step S200, the user terminal device 6 displays a display screen based on the diagnostic information 16 upon reception of the diagnostic information 16 sent in step S250, and thus the diagnostic result of the comparison device with respect to the reference device is confirmed by the operator. In the information processing method described above, step S210 corresponds to a diagnostic condition reception process, step S220 corresponds to a reference information acquisition process, step S230 corresponds to a comparison information acquisition process, step S240 corresponds to a diagnostic processing process, and step S250 corresponds to an output processing process.

As described above, according to the information processing device 5A and the information processing method according to this embodiment, the diagnostic information 16 for the reference information 10-A and the comparison information 10-B is generated by inputting, to the learning model 18, the reference information 10-A including the reference processing quantity WPH-A and the reference device information 11-A in the reference device corresponding to the substrate processing apparatus 2 serving as the reference, and the comparison information 10-B including the comparison processing quantity WPH-B and the comparison device information 11-B in the comparison device corresponding to the substrate processing apparatus 2 serving as the comparison target of the reference device. Thus, it is possible to diagnose the state of the substrate processing apparatus 2 quickly and accurately.

### Second Embodiment

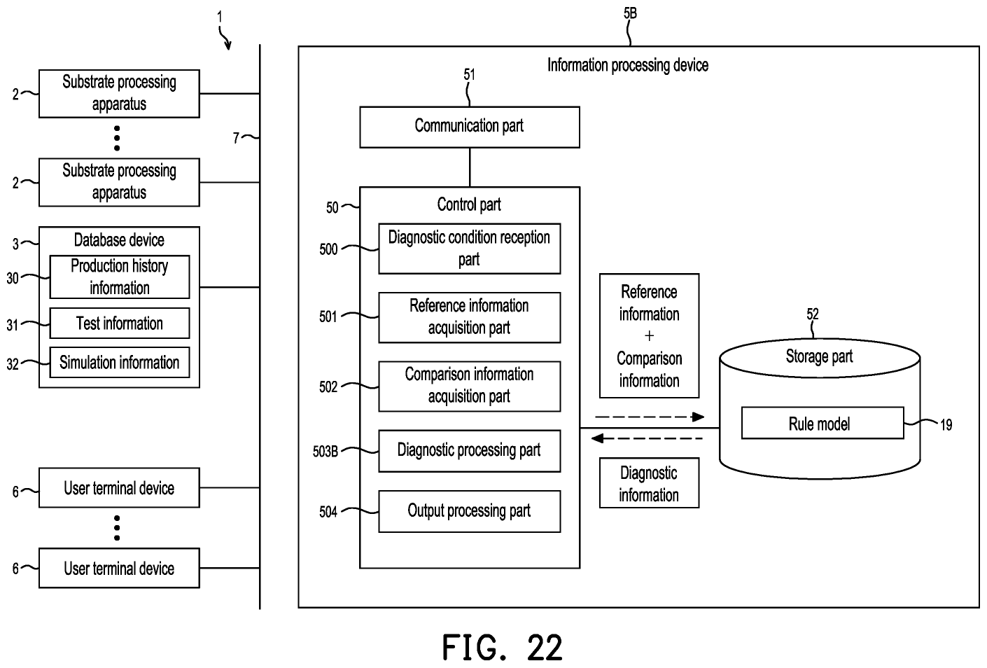

FIG. 22 is a block diagram showing an example of an information processing device 5B according to a second embodiment. The information processing device 5B according to the second embodiment differs from the information processing device 5A according to the first embodiment in that a diagnostic processing part 503B generates diagnostic information 16 using a rule model 19. Other configurations and actions of the information processing device 5B are similar to those in the first embodiment, so the same reference signs will be labeled and detailed descriptions thereof will be omitted. In the second embodiment, at least one of the database device 3 and the machine learning device 4 may be omitted.

The diagnostic processing part 503B generates diagnostic information 16 for reference information 10-A and comparison information 10-B from the reference information 10-A acquired by the reference information acquisition part 501 and the comparison information 10-B acquired by the comparison information acquisition part 502 based on the rule model 19 stored in the storage part 52. The storage part 52 may be replaced with a storage part of an external computer, and in that case, the diagnostic processing part 503B may access the external computer.

Specifically, the diagnostic processing part 503B acquires at least one of: a difference value of each device setting item of the time when the device setting information 12 included in the reference device information 11-A is compared with the device setting information 12 included in the comparison device information 11-B based on a setting value unit set for each device setting item; a difference value of each recipe setting item of the time when the recipe information 13 included in the reference device information 11-A is compared with the recipe information 13 included in the comparison device information 11-B based on a setting value unit set for each recipe setting item; a difference value of each consumable item of the time when the consumable information 14 included in the reference device information 11-A is compared with the consumable information 14 included in the comparison device information 11-B for each consumable item; and a difference value of each event item of the time when the event information included in the reference device information 11-A is compared with the event information 15 included in the comparison device information 11-B for each event item.

Then, based on at least one of the difference value of each device setting item, the difference value of each recipe setting item, the difference value of each consumable item, and the difference value of each event item, the diagnostic processing part 503B generates diagnostic information 16 for the reference information 10-A and the comparison information 10-B.

For example, the rule model 19 stores a conditional expression or a logical expression for branching and determining causes and countermeasures according to the magnitude relationship or the like of the difference value of each device setting item, the difference value of each recipe setting item, the difference value of each consumable item, and the difference value of each event item. Thus, the diagnostic processing part 503B generates the diagnostic information 16 by applying the difference value of each device setting item, the difference value of each recipe setting item, and the difference value of each consumable item acquired from the reference device information 11-A and the comparison device information 11-B, to the conditional expression or the logical expression of the rule model 19.

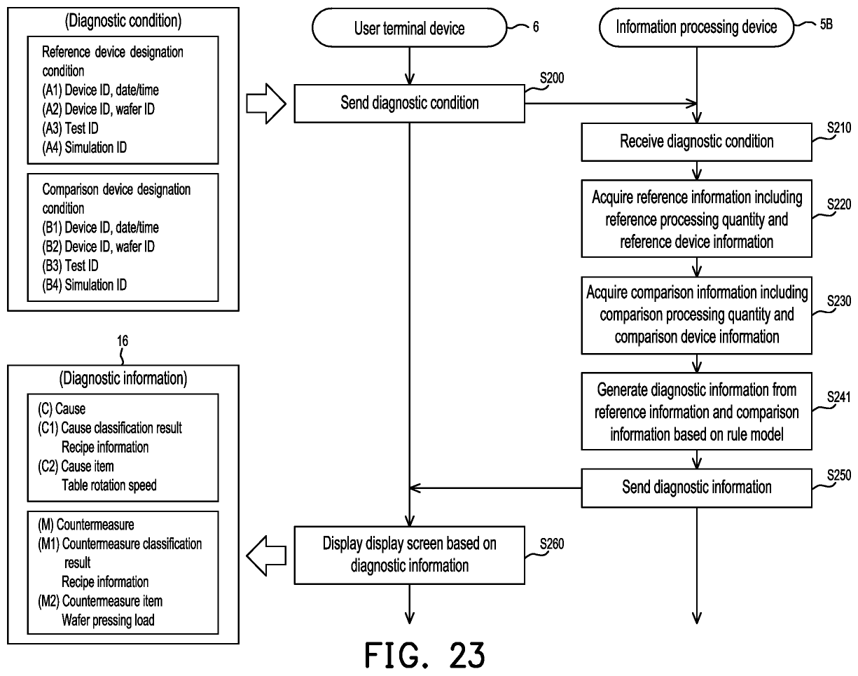

FIG. 23 is a flowchart showing an example of an information processing method performed by the information processing device 5B according to the second embodiment. The information processing method according to the second embodiment differs from the information processing device 5A according to the first embodiment in that, in step S241 (diagnostic processing process), the diagnostic processing part 503B generates the diagnostic information 16 from the reference information 10-A acquired in step S220 and the comparison information 10-B acquired in step S230 based on the rule model 19. Other aspects are similar to those in the first embodiment, so the same reference signs will be labeled and detailed descriptions thereof will be omitted.

As described above, according to the information processing device 5B and the information processing method according to this embodiment, the diagnostic information 16 for the reference information 10-A and the comparison information 10-B is generated from the reference information 10-A including the reference processing quantity WPH-A and the reference device information 11-A in the reference device corresponding to the substrate processing apparatus 2 serving as the reference, and the comparison information 10-B including the comparison processing quantity WPH-B and the comparison device information 11-B in the comparison device corresponding to the substrate processing apparatus 2 serving as the comparison target of the reference device. Thus, it is possible to diagnose the state of the substrate processing apparatus 2 quickly and accurately.

### OTHER EMBODIMENTS

The disclosure is not limited to the embodiments described above and may be implemented with various changes within the scope without departing from the spirit of the disclosure. All of such changes are included in the technical concept of the disclosure.

In the above embodiments, although the database device 3, the machine learning device 4, the information processing device 5A and 5B, and the user terminal device 6 have been described as being composed of separate devices, the four devices may also be composed of one device, and any two or three devices among the four devices may also be composed of one device. Further, at least one of the machine learning device 4 and the information processing device 5A and 5B may be incorporated into the control unit 25 of the substrate processing apparatus 2 or the user terminal device 6. For example, the learning model 18 or the rule model 19 may be stored in the storage part 62 of the user terminal device 6, and the control part 60 of the user terminal device 6 may function as the diagnostic condition reception part 500, the reference information acquisition part 501, the comparison information acquisition part 502, and the diagnostic processing parts 503A and 503B.

In the above embodiments, although the substrate processing apparatus 2 has been described as one that performs a chemical-mechanical polishing processing as the polishing processing, the substrate processing apparatus 2 may also perform a physical-mechanical polishing processing instead of the chemical-mechanical polishing processing. Further, although the substrate processing apparatus 2 has been described as one that performs a polishing processing and a finishing processing on the wafer W as the substrate processing, the substrate processing apparatus 2 may also perform any of the polishing processing and the finishing processing, and may perform other substrate processings in addition to or instead of the polishing processing and the finishing processing.

In the above embodiments, it has been described that the substrate processing apparatus 2 includes each substrate processing unit (polishing unit and finishing unit) and each transport processing unit, as shown in FIG. 2. However, as the configuration of the substrate processing apparatus 2, the quantity, arrangement, upstream-downstream relationship, parallel relationship, and serial relationship of each substrate processing unit and each transport processing unit are not limited to the example in FIG. 2 and may be appropriately changed. For example, the quantity of the polishing unit may be one or plural, and the quantity of the finishing unit may be one or plural. Further, as the quantity of the transport processing unit, the quantity of the supply discharge robot may be one or plural, the quantity of the first to third transport robots may be one or plural, and the quantity of the transfer robot may be one or plural. Further, the positions to hand over the wafer W, the positions to cause the wafer W is temporarily stand by, etc. between each substrate processing unit and each transport processing unit may be appropriately changed, and the quantities of these positions may be increased as appropriate. In such a case, the data structure of the input data and the output data in the learning data 17 and the learning model 18 may be changed according to the configuration of each processing unit.

In the above embodiments, although it has been described that a neural network is adopted as the learning model that realizes machine learning performed by the machine learning part 401, other machine learning models may be also adopted. Examples of other machine learning models include a tree type such as decision trees and regression trees, ensemble learning such as bagging and boosting, a neural network type (including deep learning) such as recurrent neural networks, convolutional neural networks, and LSTM, a clustering type such as hierarchical clustering, non-hierarchical clustering, a k-nearest neighbor algorithm, and a k-means clustering, multivariate analysis such as principal component analysis, factor analysis, and logistic regression, support vector machine, etc. Further, the machine learning algorithm executed by the machine learning part 401 may also adopt reinforcement learning instead of supervised learning.

### (Machine Learning Program and Information Processing Program)

The disclosure may also be provided in the form of a program (machine learning program) for causing the computer 900 to function as each part included in the machine learning device 4, or a program (machine learning program) for causing the computer 900 to perform each process included in the machine learning method. Further, the disclosure may also be provided in the form of a program (information processing program) for causing the computer 900 to function as each part included in the information processing devices 5A and 5B, or a program (information processing program) for causing the computer 900 to perform each process included in the information processing method according to the above embodiments.

### (Inference Device, Inference Method, and Inference Program)

The disclosure is not only provided in the form of the information processing device 5A (information processing method or information processing program) according to the above embodiments, but may also be provided in the form of an inference device (inference method or inference program) for inferring diagnostic information. In that case, a memory and a processor may be included as the inference device (inference method or inference program), and this processor may perform a series of processings. The series of processings include a reference information acquisition processing (reference information acquisition process) of acquiring a reference processing quantity and reference device information as reference information 10-A, a comparison information acquisition processing (comparison information acquisition process) of acquiring a comparison processing quantity and comparison device information as comparison information 10-B, and an inference processing (inference process) of inferring diagnostic information 16 based on the reference information 10-A and the comparison information 10-B upon acquiring the reference information 10-A in the reference information acquisition processing and acquiring the comparison information 10-B in the comparison information acquisition processing.

By providing in the form of the inference device (inference method or inference program), it becomes possible to apply to various devices simply compared to the case of implementing a safety support device. It is readily understandable to those skilled in the art that when the inference device (inference method or inference program) infers the diagnostic information, an inference technique executed by the diagnostic information generation part may be applicable using a learned learning model generated by the machine learning device and the machine learning method according to the above embodiments.

What is claimed is:

1. An information processing device diagnosing a state of a substrate processing apparatus, the substrate processing apparatus comprising: a substrate processing unit that performs a substrate processing on a substrate; and a transport processing unit that performs a transport processing of transporting the substrate before the substrate processing and after the substrate processing,
the information processing device comprising:
a reference information acquisition part that acquires a reference processing quantity and reference device information as reference information, wherein the reference processing quantity indicates a processing quantity of the substrate per unit time of a time when a reference processing action repeating the substrate processing and the transport processing is performed in a reference device corresponding to the substrate processing apparatus serving as a reference, and the reference device information is related to the reference device of the time when the reference processing action is performed;
a comparison information acquisition part that acquires a comparison processing quantity and comparison device information as comparison information, wherein the comparison processing quantity indicates a processing quantity of the substrate per unit time of a time when a comparison processing action repeating the substrate processing and the transport processing is performed in a comparison device corresponding to the substrate processing apparatus serving as a comparison target of the reference device, and the comparison device information is related to the comparison device of the time when the comparison processing action is performed; and
a diagnostic processing part that generates diagnostic information comprising at least one of a cause of a time when a difference occurs between the reference processing quantity and the comparison processing quantity and a countermeasure for eliminating the difference, based on the reference information acquired by the reference information acquisition part and the comparison information acquired by the comparison information acquisition part.

2. The information processing device according to claim 1, wherein
the reference device information comprises at least one of:
device setting information that defines an action content of the reference device of the time when the reference processing action is performed, by setting a setting value respectively for each of a plurality of device setting items;
recipe information that defines a processing content of the substrate processing of the time when the reference processing action is performed, by setting a setting value respectively for each of a plurality of recipe setting items;
consumable information that defines, for each consumable item, a status of a consumable used in the reference device when the reference processing action is performed; and
event information that defines, for each event item, a content of an event which occurs in the reference device when the reference processing action is performed, and
the comparison device information comprises at least one of:
device setting information that defines an action content of the comparison device of a time when the comparison processing action is performed, by setting a setting value respectively for each of a plurality of device setting items;
recipe information that defines a processing content of the substrate processing of the time when the comparison processing action is performed, by setting a setting value respectively for each of a plurality of recipe setting items;
consumable information that defines, for each consumable item, a consumption status of a consumable used in the comparison device when the comparison processing action is performed; and
event information that defines, for each event item, a content of an event which occurs in the comparison device when the comparison processing action is performed.

3. The information processing device according to claim 2, wherein
the diagnostic information comprises at least one of:
a cause classification result that classifies the cause into a plurality of cause types; and
a countermeasure classification result that classifies the countermeasure into a plurality of countermeasure types,
the cause types comprise at least one of:
a cause attributable to the device setting information;
a cause attributable to the recipe information;
a cause attributable to the consumable; and
a mechanical cause of the substrate processing apparatus, and
the countermeasure types comprise at least one of:
a countermeasure related to the device setting information;
a countermeasure related to the recipe information;
a countermeasure related to the consumable; and
a mechanical countermeasure of the substrate processing apparatus.

4. The information processing device according to claim 3, wherein
the diagnostic information comprises at least one of:
a cause item specified by at least one of the device setting item, the recipe setting item, the consumable item, and a mechanical adjustment item capable of being mechanically adjusted in the substrate processing apparatus, as an item related to the cause; and
a countermeasure item specified by at least one of the device setting item, the recipe setting item, the consumable item, and the mechanical adjustment item, as an item related to the countermeasure.

5. The information processing device according to claim 2, wherein
the diagnostic processing part acquires at least one of:
a difference value of each device setting item of a time when the device setting information included in the reference device information is compared with the device setting information included in the comparison device information based on a setting value unit set for each device setting item;
a difference value of each recipe setting item of a time when the recipe information included in the reference device information is compared with the recipe information included in the comparison device information based on a setting value unit set for each recipe setting item;
a difference value of each consumable item of a time when the consumable information included in the reference device information is compared with the consumable information included in the comparison device information for each consumable item; and
a difference value of each event item of a time when the event information included in the reference device information is compared with the event information included in the comparison device information for each event item, and
generates the diagnostic information for the reference information and the comparison information based on at least one of the difference value of each device setting item, the difference value of each recipe setting item, the difference value of each consumable item, and the difference value of each event item.

6. The information processing device according to claim 1, wherein
the diagnostic processing part generates the diagnostic information for the reference information and the comparison information by inputting the reference information acquired by the reference information acquisition part and the comparison information acquired by the comparison information acquisition part to a learning model that has been caused to learn, by machine learning, a correlation of the reference information and the comparison information with the diagnostic information.

7. An inference device comprising a memory and a processor and diagnosing a state of a substrate processing apparatus, the substrate processing apparatus comprising: a substrate processing unit that performs a substrate processing on a substrate; and a transport processing unit that performs a transport processing of transporting the substrate before the substrate processing and after the substrate processing,
the inference device performing:
a reference information acquisition processing of acquiring a reference processing quantity and reference device information as reference information, wherein the reference processing quantity indicates a processing quantity of the substrate per unit time of a time when a reference processing action repeating the substrate processing and the transport processing is performed in a reference device corresponding to the substrate processing apparatus serving as a reference, and the reference device information is related to the reference device of the time when the reference processing action is performed;
a comparison information acquisition processing of acquiring a comparison processing quantity and comparison device information as comparison information, wherein the comparison processing quantity indicates a processing quantity of the substrate per unit time of a time when a comparison processing action repeating the substrate processing and the transport processing is performed in a comparison device corresponding to the substrate processing apparatus serving as a comparison target of the reference device, and the comparison device information is related to the comparison device of the time when the comparison processing action is performed; and
an inference processing of inferring diagnostic information comprising at least one of a cause of a time when a difference occurs between the reference processing quantity and the comparison processing quantity and a countermeasure for eliminating the difference based on the reference information and the comparison information, upon acquiring the reference information in the reference information acquisition processing and acquiring the comparison information in the comparison information acquisition processing.

8. A machine learning device generating a learning model for diagnosing a state of a substrate processing apparatus, the substrate processing apparatus comprising: a substrate processing unit that performs a substrate processing on a substrate; and a transport processing unit that performs a transport processing of transporting the substrate before the substrate processing and after the substrate processing,
the machine learning device comprising:
a learning data storage part that stores a plurality of sets of learning data composed of an input data and an output data;
a machine learning part that causes the learning model to learn a correlation between the input data and the output data by inputting the plurality of sets of learning data to the learning model; and
a learned model storage part that stores the learning model which has been caused to learn the correlation by the machine learning part, wherein
the input data is
reference information comprising a reference processing quantity and reference device information, wherein the reference processing quantity indicates a processing quantity of the substrate per unit time of a time when a reference processing action repeating the substrate processing and the transport processing is performed in a reference device corresponding to the substrate processing apparatus serving as a reference, and the reference device information is related to the reference device of the time when the reference processing action is performed; and
comparison information comprising a comparison processing quantity and comparison device information, wherein the comparison processing quantity indicates a processing quantity of the substrate per unit time of a time when a comparison processing action repeating the substrate processing and the transport processing is performed in a comparison device corresponding to the substrate processing apparatus serving as a comparison target of the reference device, and the comparison device information is related to the comparison device of the time when the comparison processing action is performed, and
the output data is diagnostic information comprising at least one of a cause of a time when a difference occurs between the reference processing quantity and the comparison processing quantity and a countermeasure for eliminating the difference.
